(19) United States
(12) Patent Application Publication
(10) Pub. No.: US 2026/0271295 A1
(43) Pub. Date: Sep. 10, 2026

(54) SEMICONDUCTOR MEMORY DEVICE

(71) Applicant: Kioxia Corporation, Tokyo (JP)

(72) Inventor: Tomoki IGARASHI, Yokkaichi Mie (JP)

(73) Assignee: Kioxia Corporation, Tokyo (JP)

(21) Appl. No.: 19/234,025

(22) Filed: Jun. 10, 2025

(30) Foreign Application Priority Data
Mar. 4, 2025 (JP) 2025-033474

(51) Int. Cl. H10B 43/35; H10B 43/27

(52) U.S. Cl. CPC H10B 43/35; H10B 43/27

(57) ABSTRACT

According to one embodiment, in a semiconductor memory device, a first select gate line is connected to a gate of a first select transistor and a gate of a third select transistor. A second select gate line is connected to a gate of a second select transistor and a gate of a fourth select transistor. A plurality of word lines correspond to a plurality of first memory cell transistors. The plurality of word lines correspond to a plurality of second memory cell transistors. Each of the plurality of word lines is connected to a gate of a corresponding first memory cell transistor and a gate of a corresponding second memory cell transistor. Each of states of the first select transistor, the second select transistor, the third select transistor, and the fourth select transistor is capable of being set between three levels or five or more levels.

### CROSS-REFERENCE TO RELATED APPLICATIONS

This application is based upon and claims the benefit of Japanese Patent Application No. 2025-033474, filed on Mar. 4, 2025; the entire contents of which are incorporated herein by reference.

### FIELD

Embodiments described herein relate generally to a semiconductor memory device.

### BACKGROUND

In a semiconductor memory device including a plurality of memory strings each provided with a select transistor and a plurality of memory cells, the memory string is selected according to a voltage supplied to a gate of the select transistor. Here, it is desirable to efficiently select a memory string.

### BRIEF DESCRIPTION OF THE DRAWINGS

FIG. 1 is a block diagram illustrating a configuration of a semiconductor memory device according to a first embodiment;

FIG. 2 is a perspective view illustrating a configuration of a memory cell array in the first embodiment;

FIG. 3 is a diagram illustrating a relationship between the number of layers of select gate lines and a divisor of memory strings in the first embodiment;

FIG. 4 is a circuit diagram illustrating a configuration of a block in the first embodiment;

FIG. 5 is a diagram illustrating a threshold distribution of a select transistor in the first embodiment;

FIG. 6 is a cross-sectional view illustrating a configuration and an operation of the block in the first embodiment;

FIG. 7 is a diagram illustrating a state set for the select transistor in the first embodiment;

FIGS. 8A to 8I are diagrams each illustrating a threshold value and an applied voltage of the select transistor in the first embodiment;

FIG. 9 is a circuit diagram illustrating a configuration of a block in a modification of the first embodiment;

FIG. 10 is a cross-sectional view illustrating a configuration and an operation of the block in the modification of the first embodiment;

FIGS. 11A and 11B are diagrams each illustrating a state set for a select transistor in the modification of the first embodiment;

FIG. 12 is a diagram illustrating a relationship between the number of layers of select gate lines and a divisor of memory strings in a second embodiment;

FIG. 13 is a circuit diagram illustrating a configuration of a block in the second embodiment;

FIG. 14 is a diagram illustrating a threshold distribution of a select transistor in the second embodiment;

FIG. 15 is a cross-sectional view illustrating a configuration and an operation of the block in the second embodiment;

FIG. 16 is a diagram illustrating a state set for the select transistor in the second embodiment;

FIGS. 17A to 17I are diagrams each illustrating a threshold value and an applied voltage of the select transistor in the second embodiment;

FIG. 18 is a cross-sectional view illustrating a configuration and an operation of a block in a first modification of the second embodiment;

FIG. 19 is a diagram illustrating a state set for a select transistor in the first modification of the second embodiment;

FIGS. 20A to 201 are diagrams each illustrating a threshold value and an applied voltage of the select transistor in the first modification of the second embodiment;

FIG. 21 is a circuit diagram illustrating a configuration of a block in a second modification of the second embodiment;

FIG. 22 is a cross-sectional view illustrating a configuration of the block in the second modification of the second embodiment;

FIGS. 23A and 23B are diagrams each illustrating a state set for a select transistor in the second modification of the second embodiment;

FIG. 24 is a diagram illustrating a relationship between the number of layers of select gate lines and a divisor of memory strings in a third embodiment;

FIG. 25 is a circuit diagram illustrating a configuration of a block in the third embodiment; and

FIG. 26 is a diagram illustrating a threshold distribution of a select transistor in the third embodiment.

### DETAILED DESCRIPTION

In general, according to one embodiment, a semiconductor memory device includes a first memory string, a second memory string, a first select gate line, a second select gate line, and a plurality of word lines. The first memory string includes a first select transistor, a second select transistor, and a plurality of first memory cell transistors. The second select transistor is connected to the first select transistor. The plurality of first memory cell transistors are connected to the second select transistor. The second memory string includes a third select transistor, a fourth select transistor, and a plurality of second memory cell transistors. The fourth select transistor is connected to the third select transistor. The plurality of second memory cell transistors are connected to the fourth select transistor. The first select gate line is connected to a gate of the first select transistor and a gate of a third transistor. The second select gate line is connected to a gate of the second select transistor and a gate of a fourth transistor. The plurality of word lines correspond to the plurality of first memory cell transistors. The plurality of word lines correspond to the plurality of second memory cell transistors. Each of the plurality of word lines is connected to a gate of a corresponding first memory cell transistor and a gate of a corresponding second memory cell transistor. Each of states of the first select transistor, the second select transistor, the third select transistor, and the fourth select transistor is capable of being set between three levels or five or more levels.

Exemplary embodiments of a semiconductor memory device will be explained below in detail with reference to the accompanying drawings. The present invention is not limited to the following embodiments.

### First Embodiment

A semiconductor memory device according to a first embodiment includes a plurality of memory strings each including a select transistor and a plurality of memory cells, and the memory string is selected according to a voltage supplied to a gate of the select transistor, whereby a device for efficiently selecting the memory string is provided.

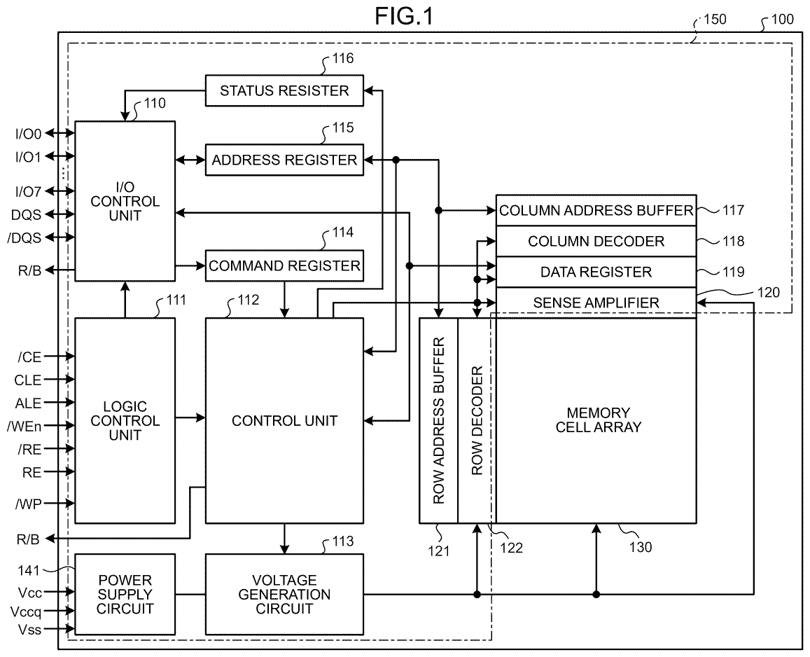

A semiconductor memory device 100 is, for example, a nonvolatile memory such as a NAND flash memory, and may be configured as illustrated in FIG. 1. The semiconductor memory device 100 includes a memory cell array 130 and a peripheral circuit 150.

The peripheral circuit 150 includes an I/O control unit 110, a logic control unit 111, a control unit 112, a voltage generation circuit 113, a command register 114, an address register 115, a status register 116, a column address buffer 117, a column decoder 118, a data register 119, a sense amplifier 120, a row address buffer 121, a row decoder 122, a power supply circuit 141, and a clock generation circuit 142.

The logic control unit 111 receives inputs of various control signals via input pins (CE, ALE, and the like) of various control signals. The I/O control unit 110 distributes a storage destination register of an I/O signal based on the control signal received by the logic control unit 111. The logic control unit 111 transmits the received control signal to the control unit 112. CE indicated as an input pin of the logic control unit 111 indicates a chip enable pin of the semiconductor memory device 100.

The control unit 112 includes a state transition circuit (state machine) for changing a state based on various control signals received via the logic control unit 111, and controls the operation of the entire semiconductor memory device 100.

The I/O control unit 110 is a buffer circuit for transmitting and receiving I/O signals and strobe signals to and from a controller 20 via I/O signal pins I/O0 to I/O7 and strobe pins DQS and/DQS. A command, an address, and data (data to be written) fetched as an I/O signal by the I/O control unit 110 via the I/O signal pins I/O0 to I/O7 are distributed to and stored in the address register 115, the command register 114, and the data register 119, respectively.

The power supply circuit 141 receives, for example, power supply voltages Vcc, Vccq, and Vss from the controller 20 via a power supply pin, and supplies the voltages to each unit in the semiconductor memory device 100. The power supply voltage Vccq is, for example, a power supply voltage used for operation of the I/O control unit 110. The power supply voltage Vss is, for example, a ground voltage.

The control unit 112 instructs the voltage generation circuit 113 on a voltage value to be generated and a power supply timing. The control unit 112 includes the clock generation circuit 142. The clock generation circuit 142 supplies a clock signal CLK to, for example, a charge pump circuit 1. The control unit 112 transmits a ready/busy signal R/B to the controller 20.

The voltage generation circuit 113 generates a predetermined voltage under control of the control unit 112. The voltage generation circuit 113 supplies the generated voltage to the memory cell array 130, the row decoder 122, and the sense amplifier 120.

The status register 116 stores status information indicating whether writing of the memory cell array 130 is successful, status information indicating whether erasing of the memory cell array 130 is successful, and the like. The pieces of status information are transmitted as response signals to the controller 20 by the I/O control unit 110.

The memory cell array 130 is configured by arranging a plurality of memory cells, and stores write data from a host (not illustrated).

The row decoder 122, the column decoder 118, and the sense amplifier 120 execute access to the memory cell array 130 under control of the control unit 112. The row decoder 122 selects a word line corresponding to a row address and activates the selected word line. The column decoder 118 selects and activates a bit line corresponding to a column address. The bit line is electrically connectable to a memory string MS described later. The sense amplifier 120 applies a voltage to the bit line selected by the column decoder 118, and writes data stored in the data register 119 to a memory cell transistor located at an intersection of the word line selected by the row decoder 122 and the bit line (memory string MS) selected by the column decoder 118. The sense amplifier 120 reads data stored in a memory cell transistor located at an intersection of the word line selected by the row decoder 122 and the bit line (memory string MS) selected by the column decoder 118 via the bit line, and stores the read data in the data register 119. The data stored in the data register 119 is transmitted to the I/O control unit 110 via a data line, and is transmitted from the I/O control unit 110 to the outside (for example, controller).

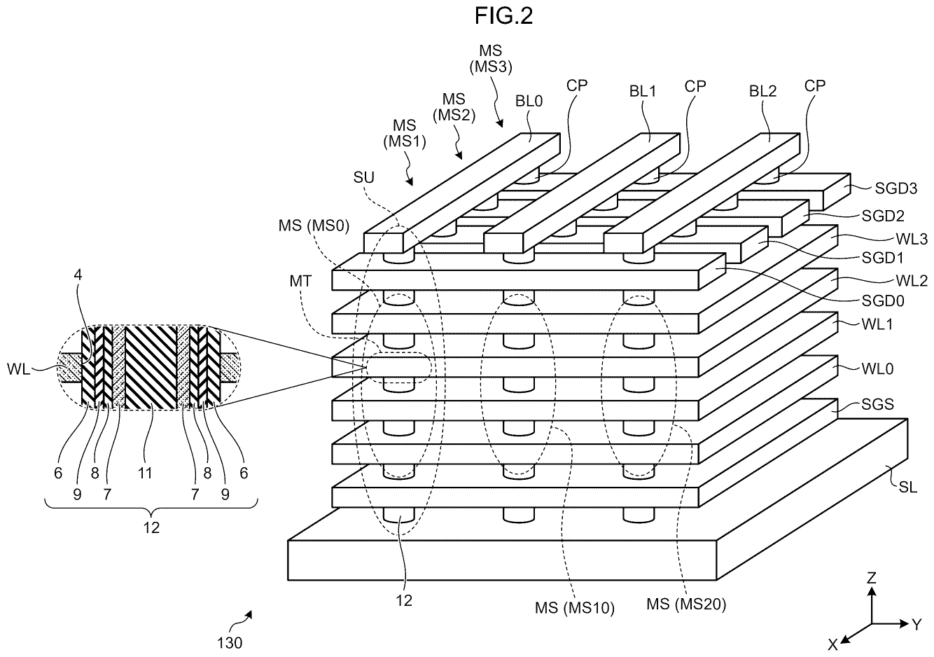

The memory cell array 130 may be configured as illustrated in FIG. 2. FIG. 2 is a perspective view illustrating a configuration of the memory cell array 130. In FIG. 2, an insulating layer and an interlayer insulating film are omitted in the drawing for simplification.

A source line SL extends in a plate-like shape above a substrate (not illustrated). Hereinafter, a direction perpendicular to a surface of the source line SL is defined as a Z direction, and two directions perpendicular to each other in a plane perpendicular to the Z direction are each defined as an X direction and a Y direction.

A select gate line SGS is formed on a +Z side of the source line SL. A plurality of layers of the word lines WL are stacked in the Z direction on a +Z side of the select gate line SGS. FIG. 2 illustrates a configuration in which four layers of word lines WL0 to WL3 are stacked. A select gate line SGD is formed on a +Z side of the word line WL3 farthest from the substrate on the +Z side. The select gate line SGD includes a plurality of select gate electrodes SGD0 to SGD3 divided in the Y direction by an insulating film SHE.

The select gate line SGS extends in an XY direction on the +Z side of the source line SL. The word lines WL0 to WL3 extend in the XY direction on the +Z side of the select gate line SGS. The select gate electrodes SGD0 to SGD3 provided in the select gate line SGS extend in the Y direction on the +Z side of the word lines WL0 to WL3.

A columnar body 12 extends in the Z direction and penetrates the select gate electrodes SGD0 to SGD3, the word lines WL0 to WL3, and the source-side select gate electrode SGS. Each of the drain side select gate electrodes SGD0 to SGD3 configures a string unit SU. That is, the string unit SU includes a plurality of memory strings MS arranged in the Y direction, and can be selectively accessed by the drain-side select gate electrodes SGD0 to SGD3.

Bit lines BL0 to BL2 extend in the X direction on the +Z side of the select gate line SGD (select gate electrodes SGD0 to SGD3). The extending direction of the bit lines BL0 to BL2 (X direction) is orthogonal to the extending direction of the drain-side select gate electrodes SGD0 to SGD3 (Y direction) and orthogonal to the stacking direction of the word lines WL0 to WL3 (Z direction). The columnar body 12 extends, for example, in the Z direction from the source line SL to the bit lines BL0 to BL2.

In the memory cell array 130, a plurality of memory cell transistors are configured at a plurality of locations at which a plurality of word lines WL and a plurality of columnar bodies 12 intersect. That is, a plurality of memory cell transistors are configured at a plurality of locations at which the plurality of word lines WL and the plurality of memory strings MS intersect. A plurality of select transistors STD are configured at a plurality of locations at which the select gate line SGD and the plurality of columnar bodies 12 intersect. That is, the plurality of select transistors STD are configured at a plurality of locations at which the select gate line SGD and the plurality of memory strings MS intersect. A plurality of select transistors STS are configured at a plurality of locations at which the select gate line SGS and the plurality of columnar bodies 12 intersect. That is, the plurality of select transistors STS are configured at a plurality of locations at which the select gate line SGS and the plurality of memory strings MS intersect.

A columnar insulator 11 is formed at a center of the columnar body 12. As a material of the columnar insulator 11, for example, a silicon oxide film may be used. A channel semiconductor film 7 is formed between an outer surface of the columnar insulator 11 and an inner surface of a through hole 4, a tunnel insulating film 8 is formed between the inner surface of the through hole 4 and the channel semiconductor film 7, a charge storage film 9 is formed between the inner surface of the through hole 4 and the tunnel insulating film 8, and a block insulating film 6 is formed between the inner surface of the through hole 4 and the charge storage film 9. For example, the channel semiconductor film 7, the tunnel insulating film 8, the charge storage film 9, and the block insulating film 6 are configured to penetrate the source-side select gate electrode SGS, the word lines WL0 to WL3, and the select gate lines SGD0 to SGD3, respectively. As the channel semiconductor film 7, for example, a semiconductor such as Si may be used. As the tunnel insulating film 8 and the block insulating film 6, for example, a silicon oxide film may be used. As the charge storage film 9, for example, a silicon nitride film or an ONO film (a three-layer structure of a silicon oxide film, a silicon nitride film, and a silicon oxide film) may be used.

It should be noted that, in the example of FIG. 2, a method of forming the columnar insulator 11 at the center of the columnar body 12 that penetrates the select gate line SGS, the word lines WL0 to WL3, and the select gate lines SGD0 to SGD3 is described, and a columnar semiconductor may be embedded instead of the columnar insulator 11.

In FIG. 2, a configuration in which four layers of memory cells MT are stacked is described, but i (i is an integer of 2 or more) layers of the memory cells MT may be stacked. Although one layer of the select gate line SGD is illustrated in FIG. 2, a plurality of layers of the select gate lines SGD may be stacked in the Z direction on the +Z side of the word line WL3 farthest from the substrate on the +Z side. Although one layer of the select gate line SGS is illustrated in FIG. 2, a plurality of layers of the select gate lines SGS may be stacked in the Z direction on the +Z side of the source line SL.

Here, when the plurality of select transistors STS configured at a plurality of locations at which the plurality of layers of the select gate lines SGS and each memory string MS intersect are capable of multi-level storage, it is possible to stack the plurality of layers of the select gate lines SGS in the Z direction and electrically divide the plurality of memory strings MS sharing a bit line BL.

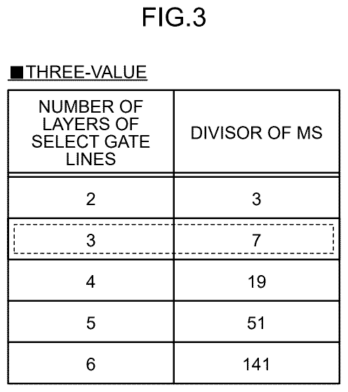

For example, when the plurality of select transistors STS are capable of three-level storage, as illustrated in FIG. 3, it is possible to stack two layers of the select gate lines SGS in the Z direction and electrically divide the memory strings MS into three at most. When three layers of the select gate lines SGS are stacked in the Z direction, as described later, it is possible to take a combination in which permutations of states of the select transistors STS are different from each other in each memory string and sums of the permutations are equal to each other and electrically divide the memory strings MS into seven at most. It is possible to stack four layers of the select gate lines SGS in the Z direction and electrically divide the memory strings MS into 19 at most. It is possible to stack five layers of the select gate lines SGS in the Z direction and electrically divide the memory strings MS into 51 at most. It is possible to stack six layers of the select gate lines SGS in the Z direction and electrically divide the memory strings MS into 141 at most.

As illustrated in FIG. 3, when the plurality of select transistors STS are capable of three-level storage, the number of layers of the select gate lines SGS per divisor of the memory strings MS can be reduced by electrical division. That is, by multi-level storage of each select transistor STS, it is possible to secure a large divisor of the memory strings MS while reducing the number of layers of the select gate lines SGS and efficiently perform electrical division of the memory strings MS.

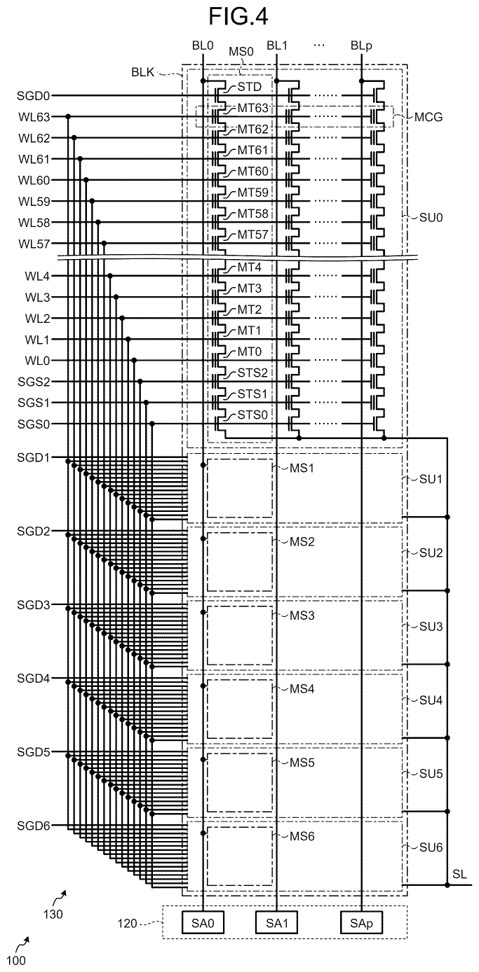

When each select transistor STS is capable of three-level storage and three layers of the select gate lines SGS0 to SGS2 are stacked in the Z direction, the memory cell array 130 may be configured as illustrated in FIG. 4 since the memory strings MS can be electrically divided into seven at most. FIG. 4 is a circuit diagram illustrating a configuration of a block BLK.

The memory cell array 130 includes a plurality of blocks BLK. Each block BLK includes seven string units SU0 to SU6 as illustrated in FIG. 4 since the memory strings MS can be electrically divided into seven at most. The seven string units SU0 to SU6 correspond to seven select gate electrodes SGD0 to SGD6. The seven string units SU0 to SU6 share each of the three select gate lines SGS0 to SGS2. Each of the string units SU0 to SU6 is selectively accessible by the select gate electrodes SGD0 to SGD6. The string unit SU0 includes a plurality of memory strings MS0. The string unit SU1 includes a plurality of memory strings MS1. The string unit SU2 includes a plurality of memory strings MS2. The string unit SU6 includes a plurality of memory strings MS6. The seven memory strings MS0 to MS6 across the seven string units SU0 to SU6 are commonly connected to one bit line BL.

Each memory string MS includes, for example, 64 memory cells MT (MT0 to MT63) and select transistors STD and STS0 to STS2. The memory cell MT includes a control gate and a charge storage film, and stores data in a nonvolatile manner. Similarly, each of the select transistors STS0 to STS2 includes a control gate and a charge storage film, and stores a level in a nonvolatile manner. The 64 memory cells MT (MT0 to MT63) are connected in series between a source of the select transistor STD and a drain of the select transistor STS2. The number of memory cells MT in the memory string MS is not limited to 64.

The bit lines BL0 to BLp (when each bit line is not distinguished, referred to as BL) are connected to the memory strings MS. When the select transistor STD is turned on, a channel region of each memory cell MT in the memory string MS may be conducted to the bit line BL. A corresponding sense amplifier SA among a plurality of sense amplifiers SA0 to SAp in a sense amplifier circuit SAC is connected to each bit line BL.

The word lines WL0 to WL63 (when each word line is not distinguished, referred to as WL) commonly connect control gates of the memory cells MT between the memory strings MS in each string unit SU in the physical block BLK. That is, the control gates of the memory cells MT in the same row in each string unit SU in the physical block BLK are connected to the same word line WL. That is, the string unit SU of the physical block BLK includes a plurality of memory cell groups MCG corresponding to a plurality of word lines WL, and each memory cell group MCG includes (p+1) memory cells MT connected to the same word line WL. When each memory cell MT is capable of storing 1-bit level (when operation is performed in a single-level cell (SLC) mode), (p+1) memory cells MT connected to the same word line WL (that is, the memory group MCG) are handled as one physical page, and data write processing and data read processing are performed for each physical page. The number of the word lines WL is not limited to 64 illustrated in FIG. 4.

Each memory cell MT may be capable of storing a plurality of bit levels. For example, when each memory cell MT is capable of storing a level of n (n≥2) bits, a size of a storage capacity per word line WL is equal to n physical pages. That is, each memory cell group MCG is handled as n physical pages. For example, in a multi-level cell (MLC) mode in which each memory cell MT stores a 2-bit level, data of two physical pages is stored in each word line WL. Alternatively, in a triple-level cell (TLC) mode in which each memory cell MT stores a 3-bit level, data of three physical pages is stored in each word line WL. Alternatively, in a quad-level cell (QLC) mode in which each memory cell MT stores a 4-bit level, data of four physical pages is stored in each word line WL. Alternatively, in a penta-level cell (PLC) mode in which each memory cell MT stores a 5-bit level, data of five physical pages is stored in each word line WL.

Similarly, each of the select transistors STS0 to STS2 on the source side may be capable of storing a plurality of bit levels. For example, when each of the select transistors STS0 to STS2 is capable of storing a level of s (s≥2) bits, a size of a storage capacity per word line WL is equal to s physical pages. That is, each of the select transistors STS0 to STS2 is handled as s physical pages. Here, each of the select transistors STS0 to STS2 is capable of multi-level storage up to a 2^{s} level. That is, a threshold voltage of each of the select transistors STS0 to STS2 can be set between 2^{s} or less levels.

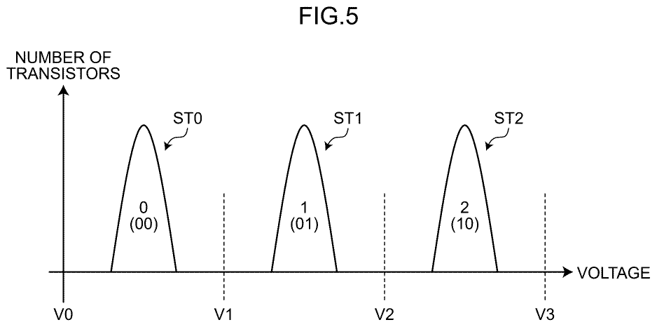

For example, when s=2 is satisfied, each of the select transistors STS0 to STS2 may be capable of three-level storage. Here, as illustrated in FIG. 5, a range in which the threshold voltage is controlled (range of V0 to V3) is divided into three states (small regions) ST0 to ST2. A different 2-bit level is associated with each of the states ST0 to ST2. In the example of FIG. 5, a boundary between the state ST0 and the state ST1 is defined as V1, and a boundary between the state ST1 and the state ST2 is defined as V2. Here, the following Equation 1 is satisfied.

$$V 0 < V 1 < V 2 < V 3 \qquad Equation 1$$

In the example of FIG. 5, the three states ST0 to ST2 correspond to 2-bit levels of “00”, “01”, and “10” from a lower-voltage side. When a level is represented by decimal notation, three states ST0 to ST2 correspond to three levels of “0”, “1”, and “2” from the lower-voltage side. That is, a 2-bit level is associated with each state in ascending order from the lower-voltage side.

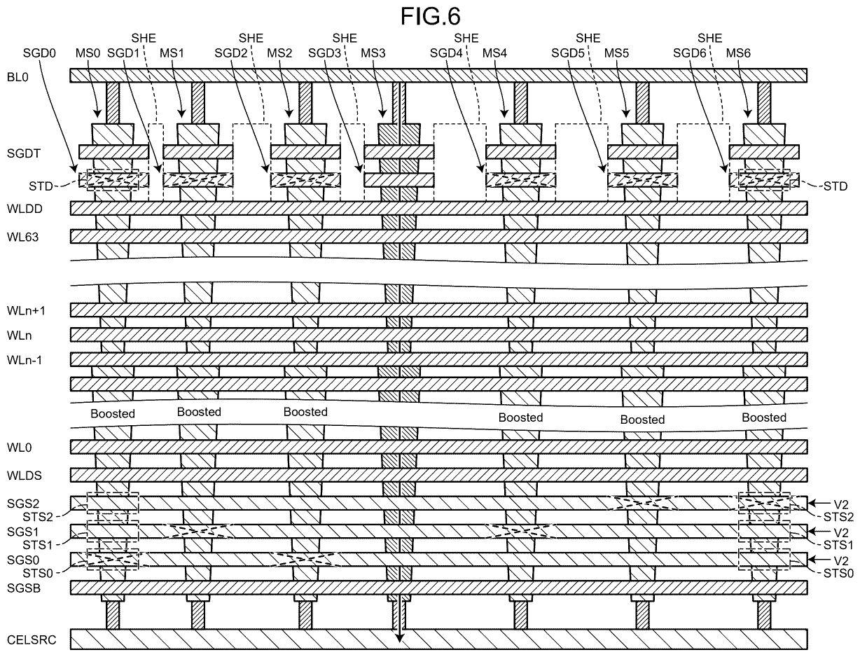

For example, 3×7=21 select transistors STS are formed at locations at which the three layers of the select gate lines SGS0 to SGS2 and the seven memory strings MS0 to MS6 illustrated in FIG. 6 intersect. FIG. 6 is a cross-sectional view illustrating a configuration and an operation of the block BLK.

Levels set to the 21 select transistors STS include seven combinations of states of the select transistors STS0, STS1, and STS2 for each of the memory strings MS0 to MS6. By making permutation patterns of states in each combination different from each other and making sums of the states in each combination equal to each other, it is possible to efficient make each memory string MS electrically independent. A sum S that maximizes the number of electrical divisions may be obtained using the following Equation 2.

$$S = int ( \frac{N * ( M - 1 )}{2} ) \qquad Equation 2$$

In Equation 2, N represents the number of select gate lines. M indicates the number of states. int( ) indicates an integer part of the number in ( ). When the number in ( ) is indivisible, S+1 is also a method of taking a sum that maximizes the number of electrical divisions. In the configuration of FIG. 6, S=3 is obtained by substituting N=3 and M=3 into Equation 2 for the source side.

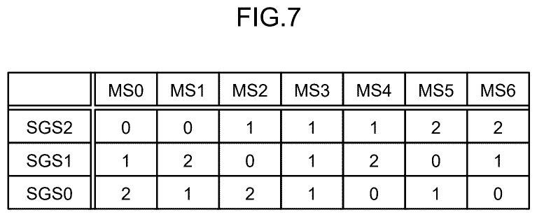

Seven combinations in which patterns of levels are different from each other and a sum of the values becomes 3 may be used and the levels of the 21 select transistors STS may be set as illustrated in FIG. 7. FIG. 7 is a diagram illustrating a state set in the select transistor STS. In FIG. 7, a level set to the select transistor STS is illustrated in decimal notation.

In the examples of FIGS. 6 and 7, the threshold voltages of the three layers of the select transistors STS0, STS1, and STS2 at the locations at which the three layers of the select gate lines SGS0, SGS1, and SGS2 and the memory string MS0 intersect are set to “2” level, “1” level, and “0” level, respectively.

The threshold voltages of the three layers of the select transistors STS0, STS1, and STS2 at the locations at which the three layers of the select gate lines SGS0, SGS1, and SGS2 and the memory string MS1 intersect are set to “1” level, “2” level, and “O” level, respectively.

The threshold voltages of the three layers of the select transistors STS0, STS1, and STS2 at the locations at which the three layers of the select gate lines SGS0, SGS1, and SGS2 and the memory string MS2 intersect are set to “2” level, “0” level, and “1” level, respectively.

The threshold voltages of the three layers of the select transistors STS0, STS1, and STS2 at the locations at which the three layers of the select gate lines SGS0, SGS1, and SGS2 and the memory string MS3 intersect are set to “1” level, “1” level, and “1” level, respectively.

The threshold voltages of the three layers of the select transistors STS0, STS1, and STS2 at the locations at which the three layers of the select gate lines SGS0, SGS1, and SGS2 and the memory string MS4 intersect are set to “0” level, “2” level, and “1” level, respectively.

The threshold voltages of the three layers of the select transistors STS0, STS1, and STS2 at the locations at which the three layers of the select gate lines SGS0, SGS1, and SGS2 and the memory string MS5 intersect are set to “2” level, “0” level, and “1” level, respectively.

The threshold voltages of the three layers of the select transistors STS0, STS1, and STS2 at the locations at which the three layers of the select gate lines SGS0, SGS1, and SGS2 and the memory string MS6 intersect are set to “0” level, “1” level, and “2” level, respectively.

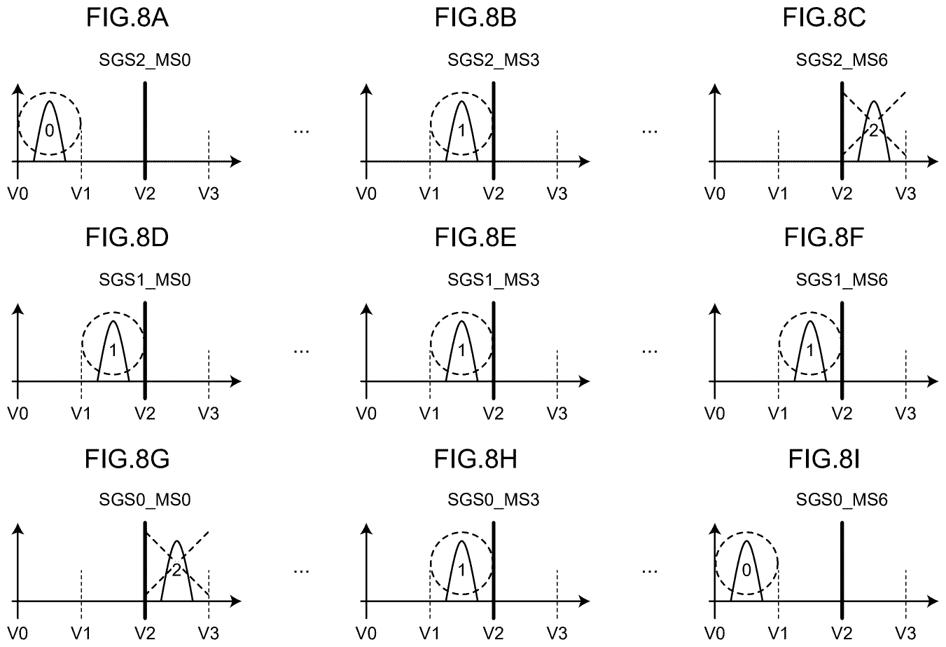

For example, as illustrated in FIGS. 6, 8A, and 3B, electrical division that selectively conducts the memory string MS3 among the seven memory strings MS0 to MS6 and cuts off the other memory strings MS0 to MS2 and MS4 to MS6 can be implemented by applying a control voltage V2 to each of the three layers of the select gate lines SGS0, SGS1, and SGS2. FIGS. 8A and 3B are diagrams illustrating a threshold value and an applied voltage of the select transistor STS.

When the control voltage V2 is applied to each of the three layers of the select gate lines SGS0, SGS1, and SGS2, the three select transistors STS0, STS1, and STS2 of the memory string MS0 illustrated in FIGS. 6, 7, 8G, 8D, and 8A enter an off state, an on state, and an on state, respectively, and are cut off on the source side.

The three select transistors STS0, STS1, and STS2 of the memory string MS1 illustrated in FIGS. 6 and 7 enter an on state, an off state, and an on state, respectively, and are cut off on the source side.

The three select transistors STS0, STS1, and STS2 of the memory string MS2 illustrated in FIGS. 6 and 7 enter an off state, an on state, and an on state, respectively, and are cut off on the source side.

The three select transistors STS0, STS1, and STS2 of the memory string MS3 illustrated in FIGS. 6, 7, 8H, 8E, and 8B enter an on state, an on state, and an on state, respectively, and are selectively conducted on the source side.

The three select transistors STS0, STS1, and STS2 of the memory string MS4 illustrated in FIGS. 6 and 7 enter an on state, an off state, and an on state, respectively, and are cut off on the source side.

The three select transistors STS0, STS1, and STS2 of the memory string MS5 illustrated in FIGS. 6 and 7 enter an on state, an on state, and an off state, respectively, and are cut off on the source side.

The three select transistors STS0, STS1, and STS2 of the memory string MS6 illustrated in FIGS. 6, 7, 8I, 8F, and 8C enter an on state, an on state, and an off state, respectively, and are cut off on the source side.

As a result, on the source side, electrical division in which the memory string MS3 among the seven memory strings MS0 to MS6 is selectively conducted and the other memory strings MS0 to MS2 and MS4 to MS6 are cut off can be implemented.

On the drain side, the select gate line SGD is physically divided into seven select gate electrodes SGD0 to SGS6 by the insulating film SHE illustrated in FIG. 6. Seven select transistors STD are formed at locations at which the seven select gate electrodes SGD0 to SGS6 and the seven memory strings MS0 to MS6 intersect. A select potential is applied to the select gate electrode SGD3, and a non-select potential is applied to the other select gate electrodes SGD0 to SGS2 and SGD4 to SGS6. As a result, the select transistor STD at a location at which the select gate electrode SGD3 and the memory string MS3 intersect is selectively turned on, and the other six select transistors STD are turned off. As a result, the memory string MS3 is selectively conducted on the drain side and the other memory strings MS0 to MS2 and MS4 to MS6 are cut off.

As described above, in the first embodiment, each select transistor STS is capable of multi-level storage in the semiconductor memory device 100. For example, each select transistor STS is capable of three-level storage. As a result, it is possible to secure a large divisor of electrical division of the memory strings MS while reducing the number of layers of the select gate lines SGS and efficiently perform electrical division of the memory strings MS.

Note that, when each select transistor STS is capable of three-level storage and the three layers of the select gate lines SGS are stacked in the Z direction, in the memory cell array 130, each block BLK may include six or less string units SU since the memory strings MS can be electrically divided into seven at most.

Alternatively, although not illustrated, when each select transistor STS is capable of three-level storage and two layers of the select gate lines SGS are stacked in the Z direction, in the memory cell array 130, each block BLK may include K string units SU since the memory strings MS can be electrically divided into three at most. K is an integer of 1 or more and 3 or less. Here, the K string units SU correspond to K select gate electrodes SGD. The K string units SU share each of the two select gate lines SGS. Each of the string units SU is selectively accessible by the select gate electrodes SGD. Each string unit SU includes a plurality of memory strings MS. K memory strings MS across the K string units SU are commonly connected to one bit line BL.

In this way, since each select transistor STS performs three-level storage, the K memory strings MS commonly connected to one bit line BL can be electrically divided.

Alternatively, when each select transistor STS is capable of three-level storage and four layers of the select gate lines SGS are stacked in the Z direction, in the memory cell array 130, each block BLK may include K string units SU since the memory strings MS can be electrically divided into 19 at most. K is an integer of 1 or more and 19 or less. Here, the K string units SU correspond to K select gate electrodes SGD. The K string units SU share each of the four select gate lines SGS. Each of the string units SU is selectively accessible by the select gate electrodes SGD. Each string unit SU includes a plurality of memory strings MS. K memory strings MS across the K string units SU are commonly connected to one bit line BL.

In this way, since each select transistor STS performs three-level storage, the K memory strings MS commonly connected to one bit line BL can be electrically divided.

Alternatively, when each select transistor STS is capable of three-level storage and five layers of the select gate lines SGS are stacked in the Z direction, in the memory cell array 130, each block BLK may include K string units SU since the memory strings MS can be electrically divided into 51 at most. K is an integer of 1 or more and 51 or less. Here, the K string units SU correspond to K select gate electrodes SGD. The K string units SU share each of the five select gate lines SGS. Each of the string units SU is selectively accessible by the select gate electrodes SGD. Each string unit SU includes a plurality of memory strings MS. K memory strings MS across the K string units SU are commonly connected to one bit line BL.

In this way, since each select transistor STS performs three-level storage, the K memory strings MS commonly connected to one bit line BL can be electrically divided.

Alternatively, when each select transistor STS is capable of three-level storage and six layers of the select gate lines SGS are stacked in the Z direction, in the memory cell array 130, each block BLK may include K string units SU since the memory strings MS can be electrically divided into 141 at most. K is an integer of 1 or more and 141 or less. Here, the K string units SU correspond to K select gate electrodes SGD. The K string units SU share each of the six select gate lines SGS. Each of the string units SU is selectively accessible by the select gate electrodes SGD. Each string unit SU includes a plurality of memory strings MS. K memory strings MS across the K string units SU are commonly connected to one bit line BL.

In this way, since each select transistor STS performs three-level storage, the K memory strings MS commonly connected to one bit line BL can be electrically divided.

Alternatively, in each block BLK, instead of a configuration in which physical division is used on the drain side and electrical division is used on the source side, a configuration in which electrical division is used on the drain side and physical division is used on the source side may be applied, or a configuration in which electrical division is used on both the drain side and the source side may be applied.

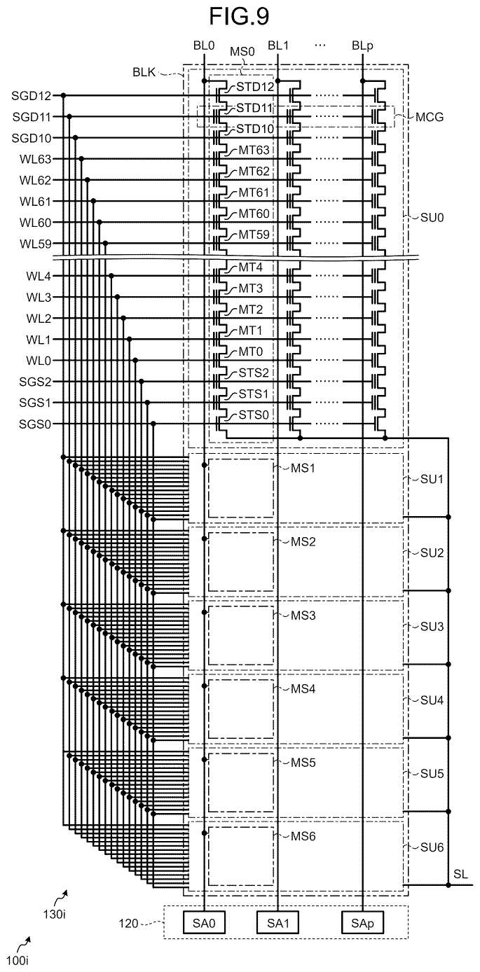

For example, as a modification of the first embodiment, when three layers of select gate lines SGD10 to SGD12 are stacked in the Z direction on the drain side and the three layers of the select gate lines SGS0 to SGS2 are stacked in the Z direction on the source side, a memory cell array 130i of a semiconductor memory device 100i may be configured as illustrated in FIG. 9. FIG. 9 is a circuit diagram illustrating a configuration of a block BLK in the modification of the first embodiment.

In the block BLK illustrated in FIG. 9, three select gate lines SGD10 to SGD12 are disposed instead of seven select gate electrodes SGD0 to SGD6 (refer to FIG. 4). The seven string units SU0 to SU6 share each of the three select gate lines SGD10 to SGD12. Each memory string MS includes select transistors STD10 to STD12 instead of the select transistors STD (refer to FIG. 4). Each of the select transistors STD10 to STD12 include a control gate and a charge storage film, and stores a level in a nonvolatile manner.

The select transistors STD10 to STD12 on the drain side may be capable of storing a plurality of bit levels. For example, when each of the select transistors STD10 to STD12 is capable of storing a level of s (s≥2) bits, a size of a storage capacity per word line WL is equal to s physical pages. That is, each of the select transistors STD10 to STD12 is handled as s physical pages. Here, each of the select transistors STD10 to STD12 is capable of multi-level storage up to a 2^{s} level. That is, threshold voltages of the select transistors STD10 to STD12 can be set between 2^{s} or less levels.

For example, when s=2 is satisfied, each of the select transistors STD10 to STD12 may be capable of three-level storage. Here, as illustrated in FIG. 5, a range in which the threshold voltage is controlled (range of V0 to V3) is divided into three states (small regions) ST0 to ST2. The three states ST0 to ST2 correspond to 2-bit levels of “00”, “01”, and “10” from the lower-voltage side. When a level is represented by decimal notation, three states ST0 to ST2 correspond to three levels of “0”, “1”, and “2” from the lower-voltage side.

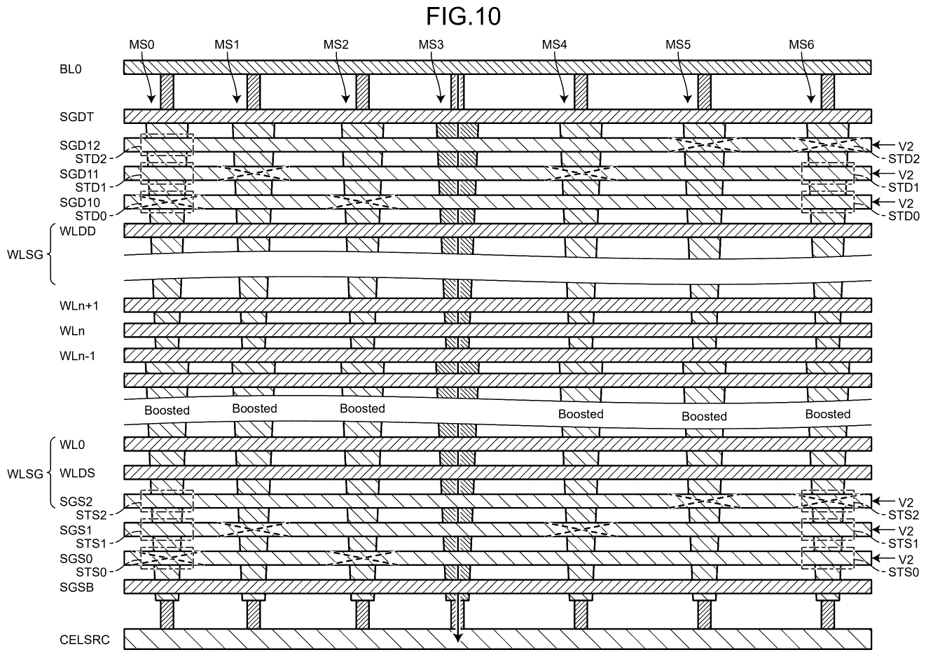

For example, 3×7=21 select transistors STD are formed at the locations at which the three layers of the select gate lines SGD10 to SGD12 and the seven memory strings MS0 to MS6 illustrated in FIG. 10 intersect. FIG. 10 is a cross-sectional view illustrating a configuration and an operation of the block BLK in the modification of the first embodiment.

In the configuration of FIG. 10, S=3 is obtained by substituting N=3 and M=3 into Equation 2 for the drain side. S=3 is obtained by substituting N=3 and M=3 into Equation 2 for the source side.

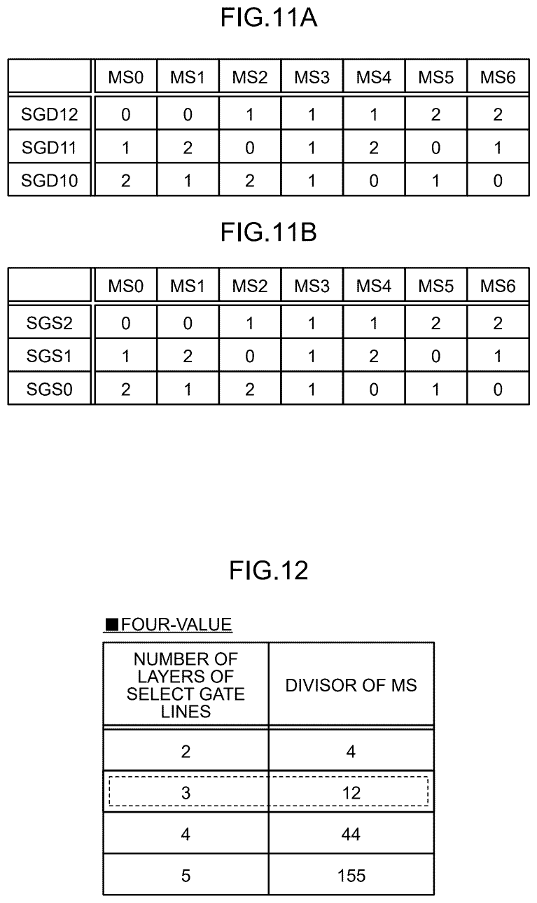

Seven combinations in which patterns of levels are different from each other and a sum of the values becomes 3 may be used and the levels of the 21 select transistors STD may be set as illustrated in FIG. 11A or the levels of the 21 select transistors STS may be set as illustrated in FIG. 11B. FIGS. 11A and 11B are diagrams illustrating states set to the select transistors STD and STS. In FIGS. 11A and 11B, the levels set to the select transistors STD and STS are illustrated in decimal notation.

Here, a combination of states of three select transistors STD1, STD2, and STD3 and a combination of states of three select transistors STS0, STS1, and STS2 may have the same level pattern for each of the memory strings MS0 to MS6.

In the examples of FIGS. 10, 11A, and 11B, the threshold voltages of the three layers of the select transistors STD10, STD11, and STD12 at the locations at which the three layers of the select gate lines SGD10, SGD11, and SGD12 and the memory string MS0 intersect are set to “2” level, “1” level, and “O” level, respectively.

The threshold voltages of the three layers of the select transistors STD10, STD11, and STD12 at the locations at which the three layers of the select gate lines SGD10, SGD11, and SGD12 and the memory string MS1 intersect are set to “1” level, “2” level, and “O” level, respectively.

The threshold voltages of the three layers of the select transistors STD10, STD11, and STD12 at the locations at which the three layers of the select gate lines SGD10, SGD11, and SGD12 and the memory string MS2 intersect are set to “2” level, “0” level, and “1” level, respectively.

The threshold voltages of the three layers of the select transistors STD10, STD11, and STD12 at the locations at which the three layers of the select gate lines SGD10, SGD11, and SGD12 and the memory string MS3 intersect are set to “1” level, “1” level, and “1” level, respectively.

The threshold voltages of the three layers of the select transistors STD10, STD11, and STD12 at the locations at which the three layers of the select gate lines SGD10, SGD11, and SGD12 and the memory string MS4 intersect are set to “0” level, “2” level, and “1” level, respectively.

The threshold voltages of the three layers of the select transistors STD10, STD11, and STD12 at the locations at which the three layers of the select gate lines SGD10, SGD11, and SGD12 and the memory string MS5 intersect are set to “1” level, “0” level, and “2” level, respectively.

The threshold voltages of the three layers of the select transistors STD10, STD11, and STD12 at the locations at which the three layers of the select gate lines SGD10, SGD11, and SGD12 and the memory string MS6 intersect are set to “0” level, “1” level, and “2” level, respectively.

For example, as illustrated in FIG. 10, electrical division that selectively conducts the memory string MS3 among the seven memory strings MS0 to MS6 and cuts off the other memory strings MS0 to MS2 and MS4 to MS6 can be implemented by applying the control voltage V2 to each of the three layers of the select gate lines SGD10, SGD11, and SGD12.

When the control voltage V2 is applied to each of the three layers of the select gate lines SGD10, SGD11, and SGD12, three select transistors STD10, STD11, and STD12 of the memory string MS0 enter an off state, an on state, and an on state, respectively, and are cut off on the drain side.

The three select transistors STD10, STD11, and STD12 of the memory string MS1 enter an on state, an off state, and an on state, respectively, and are cut off on the drain side.

The three select transistors STD10, STD11, and STD12 of the memory string MS2 enter an off state, an on state, and an on state, respectively, and are cut off on the drain side.

The three select transistors STD10, STD11, and STD12 of the memory string MS3 enter an on state, an on state, and an on state, respectively, and are selectively conducted on the drain side.

The three select transistors STD10, STD11, and STD12 of the memory string MS4 enter an on state, an off state, and an on state, respectively, and are cut off on the drain side.

The three select transistors STD10, STD11, and STD12 of the memory string MS5 enter an on state, an on state, and an off state, respectively, and are cut off on the drain side.

The three select transistors STD10, STD11, and STD12 of the memory string MS6 enter an on state, an on state, and an off state, respectively, and are cut off on the drain side.

As a result, electrical division in which the memory string MS3 among the seven memory strings MS0 to MS6 is selectively conducted and the other memory strings MS0 to MS2 and MS4 to MS6 are cut off can be implemented on the drain side.

Here, on the source side, electrical division in which the memory string MS3 among the seven memory strings MS0 to MS6 is selectively conducted and the other memory strings MS0 to MS2 and MS4 to MS6 are cut off can be implemented as in the embodiment.

In this way, in the memory cell array 130i of the semiconductor memory device 100i, each of the select transistors STD and STS perform multi-level storage on the drain side and the source side. For example, the select transistors STD and STS perform three-level storage on each of the drain side and the source side. Accordingly, it is possible to secure a large divisor of the memory strings MS while reducing the number of layers of the select gate lines SGD and SGS on each of the drain side and the source side and efficiently perform electrical division of the memory strings MS.

### Second Embodiment

Next, a semiconductor memory device 200 according to a second embodiment will be described. Hereinafter, portions different from those of the first embodiment will be mainly described.

In the first embodiment, a configuration in which each select transistor STS perform three-level storage is exemplified, but in the second embodiment, a configuration in which each select transistor STS perform four-level storage is exemplified.

For example, when the plurality of select transistors STS are capable of four-level storage, as illustrated in FIG. 12, it is possible to stack two layers of the select gate lines SGS in the Z direction and electrically divide the memory strings MS into four at most. When the three layers of the select gate lines SGS are stacked in the Z direction, it is possible to take a combination in which permutations of states of the select transistors STS are different from each other in each memory string and sums of the permutations are equal to each other and electrically divide the memory strings MS into 12 at most. It is possible to stack four layers of the select gate lines SGS in the Z direction and electrically divide the memory strings MS into 44 at most. It is possible to stack five layers of the select gate lines SGS in the Z direction and electrically divide the memory strings MS into 155 at most.

As illustrated in FIG. 12, when the plurality of select transistors STS are capable of four-level storage, the number of layers of the select gate lines SGS per divisor of electrical division of the memory strings MS can be reduced by electrical division.

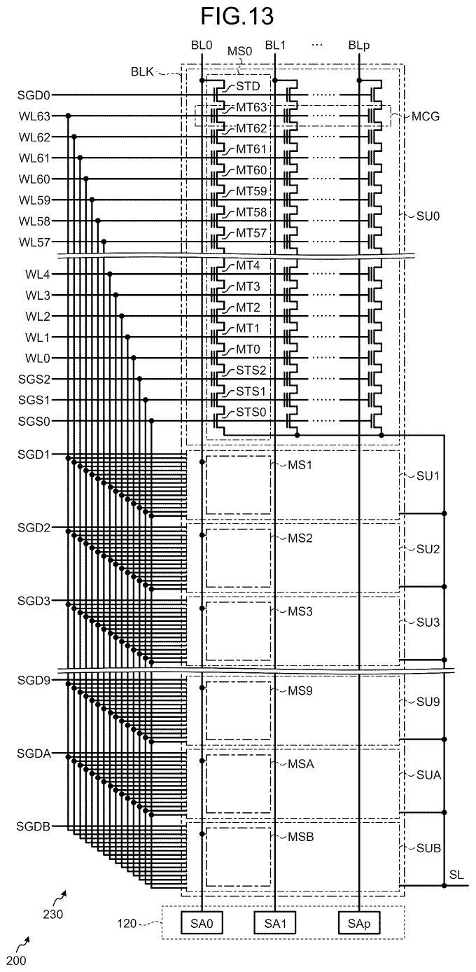

When the three layers of the select gate lines SGS0 to SGS2 are stacked in the Z direction, a memory cell array 230 of the semiconductor memory device 200 may be configured as illustrated in FIG. 13 since the memory strings MS can be electrically divided into 12 at most. FIG. 13 is a circuit diagram illustrating a configuration of a block BLK in the second embodiment.

The memory cell array 230 includes a plurality of blocks BLK. Each block BLK includes 12 string units SU0 to SUB as illustrated in FIG. 13 since the memory strings MS can be electrically divided into 12 at most. The 12 string units SU0 to SUB correspond to 12 select gate electrodes SGD0 to SGDB. The 12 string units SU0 to SUB share each of the three select gate lines SGS0 to SGS2. Each of the string units SU0 to SUB is selectively accessible by the select gate electrodes SGD0 to SGDB. The string unit SU0 includes a plurality of memory strings MS0. The string unit SU1 includes a plurality of memory strings MS1. The string unit SU2 includes a plurality of memory strings MS2. The string unit SUB includes a plurality of memory strings MSB. Each string unit SU includes a plurality of memory strings MS. 12 memory strings MS0 to MSB across the 12 string units SU0 to SUB are commonly connected to one bit line BL.

Each of the select transistors STS0 to STS2 on the source side may be capable of storing a plurality of bit levels. For example, when each of the select transistors STS0 to STS2 is capable of storing a level of s (s≥2) bits, a size of a storage capacity per word line WL is equal to s physical pages. That is, each of the select transistors STS0 to STS2 is handled as s physical pages. Here, each of the select transistors STS0 to STS2 is capable of multi-level storage up to a 2^{s} level. That is, a threshold voltage of each of the select transistors STS0 to STS2 can be set between 2^{s} or less levels.

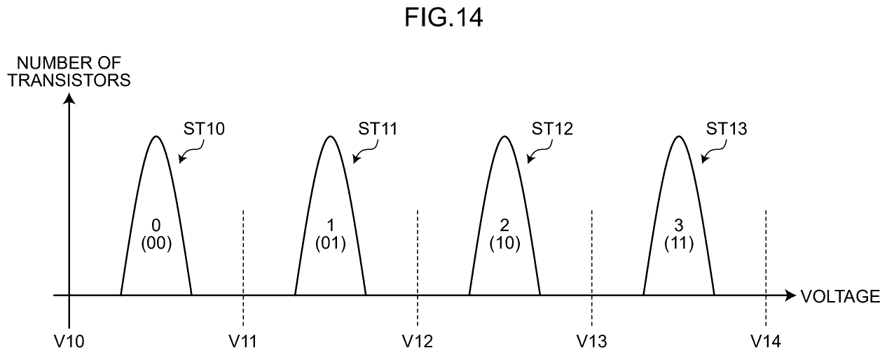

For example, when s=2 is satisfied, each of the select transistors STS0 to STS2 may be capable of four-level storage. Here, as illustrated in FIG. 14, a range in which the threshold voltage is controlled (range of V10 to V14) is divided into four states (small regions) ST10 to ST13. FIG. 14 is a diagram illustrating a threshold distribution of the select transistor STS in the second embodiment. A different 2-bit level is associated with each of the states ST10 to ST13. In the example of FIG. 14, a boundary between the state ST10 and the state ST11 is defined as V11, a boundary between the state ST11 and the state ST12 is defined as V12, and a boundary between the state ST12 and the state ST13 is defined as V13. Here, the following Equation 3 is satisfied.

$$V 10 < V 11 < V 12 < V 13 < V 14 \qquad Equation 3$$

In the example of FIG. 14, the four states ST10 to ST13 correspond to 2-bit levels of “00”, “01”, “10”, and “11” from the lower-voltage side. When a level is represented by decimal notation, four states ST10 to ST13 correspond to four levels of “0”, “1”, “2”, and “3” from the lower-voltage side. That is, a 2-bit level is associated with each state in ascending order from the lower-voltage side.

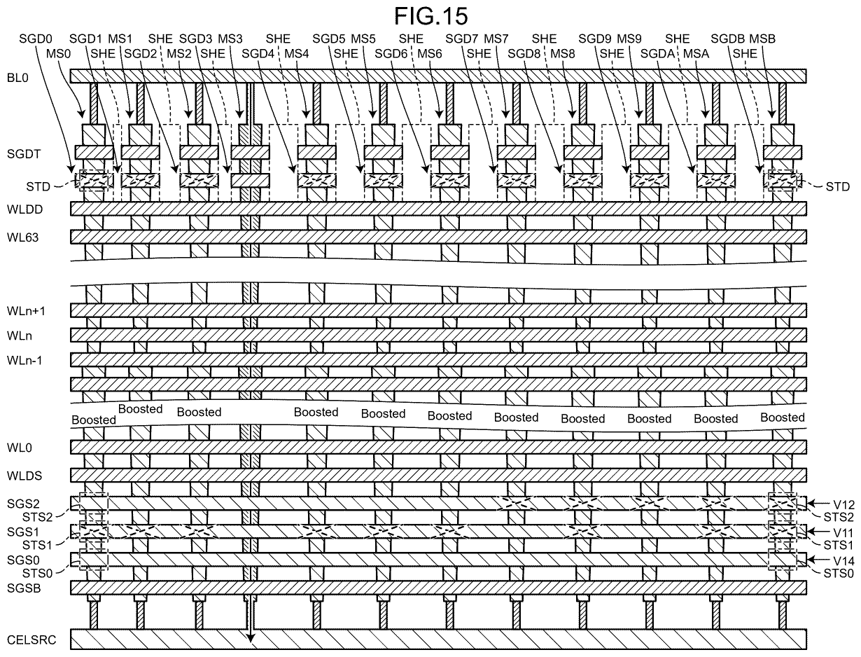

For example, 3×12=36 select transistors STS are formed at locations at which the three layers of the select gate lines SGS0 to SGS2 and the 12 memory strings MS0 to MSB illustrated in FIG. 15 intersect. FIG. 15 is a cross-sectional view illustrating a configuration and an operation of the block BLK in the second embodiment.

Levels set to the 36 select transistors STS include 12 combinations of states of the select transistors STS0, STS1, and STS2 for each of the memory strings MS0 to MSB. By making permutation patterns of states in each combination different from each other and making sums of the states in each combination equal to each other, it is possible to efficient make each memory string MS electrically independent. The sum S that maximizes the number of electrical divisions may be obtained using Equation 2.

In the configuration of FIG. 15, S=4 is obtained by substituting N=3 and M=4 into Equation 2 for the source side.

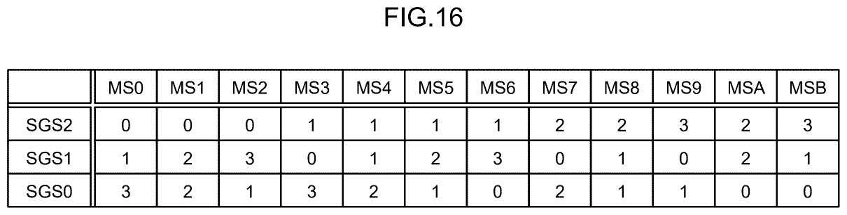

12 combinations in which patterns of levels are different from each other and a sum of the levels becomes 4 may be used and the levels of the 36 select transistors STS may be set as illustrated in FIG. 16. FIG. 16 is a diagram illustrating a state set in the select transistor STS in the second embodiment. In FIG. 16, a level set to the select transistor STS is illustrated in decimal notation.

In the examples of FIGS. 15 and 16, the threshold voltages of the three layers of the select transistors STS0, STS1, and STS2 at the locations at which the three layers of the select gate lines SGS0, SGS1, and SGS2 and the memory string MS0 intersect are set to “3” level, “1” level, and “0” level, respectively.

The threshold voltages of the three layers of the select transistors STS0, STS1, and STS2 at the locations at which the three layers of the select gate lines SGS0, SGS1, and SGS2 and the memory string MS1 intersect are set to “2” level, “2” level, and “0” level, respectively.

The threshold voltages of the three layers of the select transistors STS0, STS1, and STS2 at the locations at which the three layers of the select gate lines SGS0, SGS1, and SGS2 and the memory string MS2 intersect are set to “1” level, “3” level, and “0” level, respectively.

The threshold voltages of the three layers of the select transistors STS0, STS1, and STS2 at the locations at which the three layers of the select gate lines SGS0, SGS1, and SGS2 and the memory string MS3 intersect are set to “3” level, “O” level, and “1” level, respectively.

The threshold voltages of the three layers of the select transistors STS0, STS1, and STS2 at the locations at which the three layers of the select gate lines SGS0, SGS1, and SGS2 and the memory string MS4 intersect are set to “2” level, “1” level, and “1” level, respectively.

The threshold voltages of the three layers of the select transistors STS0, STS1, and STS2 at the locations at which the three layers of the select gate lines SGS0, SGS1, and SGS2 and the memory string MS5 intersect are set to “1” level, “2” level, and “1” level, respectively.

The threshold voltages of the three layers of the select transistors STS0, STS1, and STS2 at the locations at which the three layers of the select gate lines SGS0, SGS1, and SGS2 and the memory string MS6 intersect are set to “0” level, “3” level, and “1” level, respectively.

The threshold voltages of the three layers of the select transistors STS0, STS1, and STS2 at the locations at which the three layers of the select gate lines SGS0, SGS1, and SGS2 and the memory string MS7 intersect are set to “2” level, “0” level, and “2” level, respectively.

The threshold voltages of the three layers of the select transistors STS0, STS1, and STS2 at the locations at which the three layers of the select gate lines SGS0, SGS1, and SGS2 and the memory string MS8 intersect are set to “1” level, “1” level, and “2” level, respectively.

The threshold voltages of the three layers of the select transistors STS0, STS1, and STS2 at the locations at which the three layers of the select gate lines SGS0, SGS1, and SGS2 and the memory string MS9 intersect are set to “1” level, “0” level, and “3” level, respectively.

The threshold voltages of the three layers of the select transistors STS0, STS1, and STS2 at the locations at which the three layers of the select gate lines SGS0, SGS1, and SGS2 and the memory string MSA intersect are set to “0” level, “2” level, and “2” level, respectively.

The threshold voltages of the three layers of the select transistors STS0, STS1, and STS2 at the locations at which the three layers of the select gate lines SGS0, SGS1, and SGS2 and the memory string MSB intersect are set to “0” level, “1” level, and “3” level, respectively.

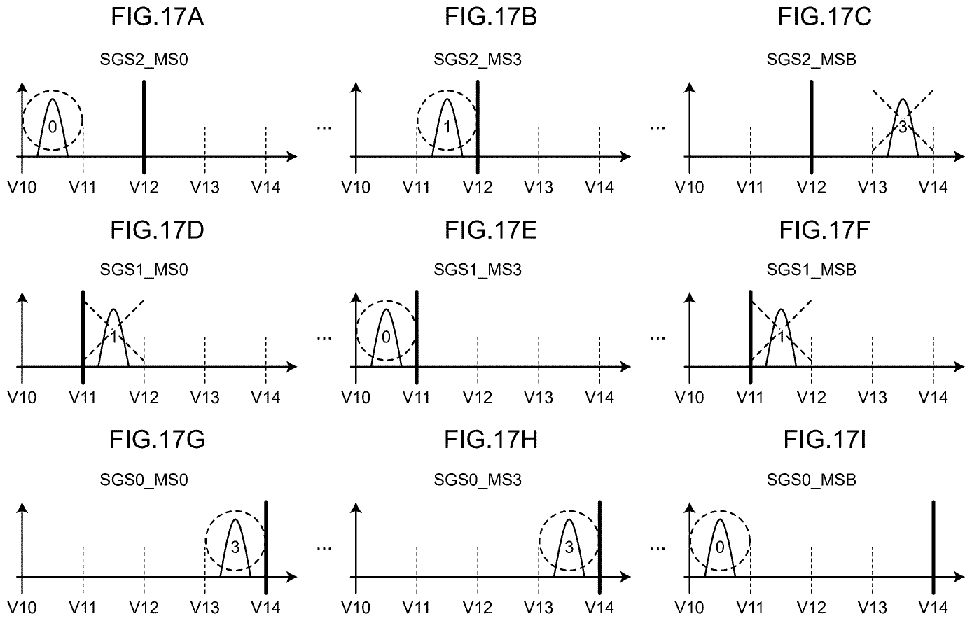

For example, as illustrated in FIGS. 15 and 17A to 17I, electrical division that selectively conducts the memory string MS3 among the 12 memory strings MS0 to MSB and cuts off the other memory strings MS0 to MS2 and MS4 to MSB can be implemented by applying control voltages V14, V11, and V12 to each of the three layers of the select gate lines SGS0, SGS1, and SGS2. FIGS. 17A to 17I are diagrams illustrating a threshold value and an applied voltage of the select transistor STS.

When the control voltages V14, V11, and V12 are applied to each of the three layers of the select gate lines SGS0, SGS1, and SGS2, the three select transistors STS0, STS1, and STS2 of the memory string MS0 illustrated in FIGS. 15, 16, 17G, 17D, and 17A enter an off state, an off state, and an on state, respectively, and are cut off on the source side.

The three select transistors STS0, STS1, and STS2 of the memory string MS1 illustrated in FIGS. 15 and 16 enter an on state, an off state, and an on state, respectively, and are cut off on the source side.

The three select transistors STS0, STS1, and STS2 of the memory string MS2 illustrated in FIGS. 15 and 16 enter an on state, an off state, and an on state, respectively, and are cut off on the source side.

The three select transistors STS0, STS1, and STS2 of the memory string MS3 illustrated in FIGS. 15, 16, 17H, 17E, and 17B enter an on state, an on state, and an on state, respectively, and are selectively conducted on the source side.

The three select transistors STS0, STS1, and STS2 of the memory string MS4 illustrated in FIGS. 15 and 16 enter an on state, an off state, and an on state, respectively, and are cut off on the source side.

The three select transistors STS0, STS1, and STS2 of the memory string MS5 illustrated in FIGS. 15 and 16 enter an off state, an on state, and an off state, respectively, and are cut off on the source side.

The three select transistors STS0, STS1, and STS2 of the memory string MS6 illustrated in FIGS. 15 and 16 enter an on state, an off state, and an off state, respectively, and are cut off on the source side.

The three select transistors STS0, STS1, and STS2 of the memory string MS7 illustrated in FIGS. 15 and 16 enter an on state, an off state, and an off state, respectively, and are cut off on the source side.

The three select transistors STS0, STS1, and STS2 of the memory string MS8 illustrated in FIGS. 15 and 16 enter an on state, an off state, and an off state, respectively, and are cut off on the source side.

The three select transistors STS0, STS1, and STS2 of the memory string MS9 illustrated in FIGS. 15 and 16 enter an on state, an on state, and an off state, respectively, and are cut off on the source side.

The three select transistors STS0, STS1, and STS2 of the memory string MSA illustrated in FIGS. 15 and 16 enter an on state, an off state, and an off state, respectively, and are cut off on the source side.

The three select transistors STS0, STS1, and STS2 of the memory string MSB illustrated in FIGS. 15, 16, 17I, 17F, and 17C enter an on state, an off state, and an off state, respectively, and are cut off on the source side.

As a result, on the source side, electrical division in which the memory string MS3 among the 12 memory strings MS0 to MSB is selectively conducted and the other memory strings MS0 to MS2 and MS4 to MSB are cut off can be implemented.

On the drain side, the select gate line SGD is physically divided into 12 select gate electrodes SGD0 to SGSB by the insulating film SHE illustrated in FIG. 15. 12 select transistors STD are formed at locations at which the 12 select gate electrodes SGD0 to SGSB and the 12 memory strings MS0 to MSB intersect. A select potential is applied to the select gate electrode SGD3, and a non-select potential is applied to the other select gate electrodes SGD0 to SGS2 and SGD4 to SGSB. As a result, the select transistor STD at a location at which the select gate electrode SGD3 and the memory string MS3 intersect is selectively turned on, and the other 11 select transistors STD are turned off. As a result, the memory string MS3 is selectively conducted on the drain side and the other memory strings MS0 to MS2 and MS4 to MSB are cut off.

As described above, in the second embodiment, each select transistor STS is capable of four-level storage in the semiconductor memory device 200. As a result, it is possible to secure a large divisor of electrical division of the memory strings MS while reducing the number of layers of the select gate lines SGS and efficiently perform electrical division of the memory strings MS.

Note that, when each select transistor STS is capable of four-level storage and the three layers of the select gate lines SGS are stacked in the Z direction, in the memory cell array 130, each block BLK may include 11 or less string units SU since the memory strings MS can be electrically divided into 12 at most.

Alternatively, although not illustrated, when each select transistor STS is capable of four-level storage and two layers of the select gate lines SGS are stacked in the Z direction, in the memory cell array 230, each block BLK may include K string units SU since the memory strings MS can be electrically divided into four at most. K is an integer of 1 or more and 4 or less. Here, the K string units SU correspond to K select gate electrodes SGD. The K string units SU share each of the two select gate lines SGS. Each of the string units SU is selectively accessible by the select gate electrodes SGD. Each string unit SU includes a plurality of memory strings MS. K memory strings MS across the K string units SU are commonly connected to one bit line BL.

In this way, since each select transistor STS performs four-level storage, K memory strings MS commonly connected to one bit line BL can be electrically divided.

Alternatively, when each select transistor STS is capable of four-level storage and four layers of the select gate lines SGS are stacked in the Z direction, in the memory cell array 130, each block BLK may include K string units SU since the memory strings MS can be electrically divided into 44 at most. K is an integer of 1 or more and 44 or less. Here, the K string units SU correspond to K select gate electrodes SGD. The K string units SU share each of the four select gate lines SGS. Each of the string units SU is selectively accessible by the select gate electrodes SGD. Each string unit SU includes a plurality of memory strings MS. K memory strings MS across the K string units SU are commonly connected to one bit line BL.

In this way, since each select transistor STS performs four-level storage, K memory strings MS commonly connected to one bit line BL can be electrically divided.

Alternatively, when each select transistor STS is capable of four-level storage and five layers of the select gate lines SGS are stacked in the Z direction, in the memory cell array 130, each block BLK may include K string units SU since the memory strings MS can be electrically divided into 155 at most. K is an integer of 1 or more and 155 or less. Here, the K string units SU correspond to K select gate electrodes SGD. The K string units SU share each of the five select gate lines SGS. Each of the string units SU is selectively accessible by the select gate electrodes SGD. Each string unit SU includes a plurality of memory strings MS. K memory strings MS across the K string units SU are commonly connected to one bit line BL.

In this way, since each select transistor STS performs four-level storage, K memory strings MS commonly connected to one bit line BL can be electrically divided.

Alternatively, when each select transistor STS is capable of four-level storage and a set level includes a plurality of combinations of states of the select transistor STS, even when the sum S of levels of states ST in each combination cannot be divided by the number in ( ) in Equation 2, maximum electrical division can be performed by setting a level obtained by adding S+1 as the sum S.

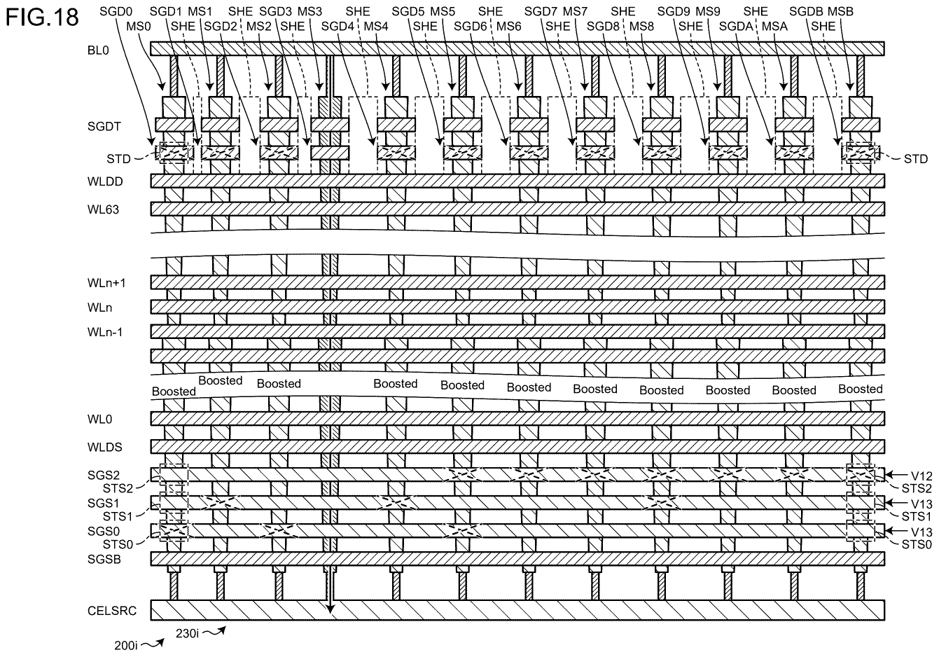

For example, as a first modification of the second embodiment, in a memory cell array 230i of a semiconductor memory device 200i illustrated in FIG. 18, 3×12=36 select transistors STS are formed at locations at which the three layers of the select gate lines SGS0 to SGS2 and the 12 memory strings MS0 to MSB intersect as in the second embodiment. FIG. 18 is a cross-sectional view illustrating a configuration and an operation of a block BLK in a first modification of the second embodiment.

Levels set to the 36 select transistors STS include 12 combinations of states of the select transistors STS0, STS1, and STS2 for each of the memory strings MS0 to MSB. The sum S of levels of states ST in each combination may be 5 (that is, S=5) obtained by adding 1 to the level obtained by Equation 2.

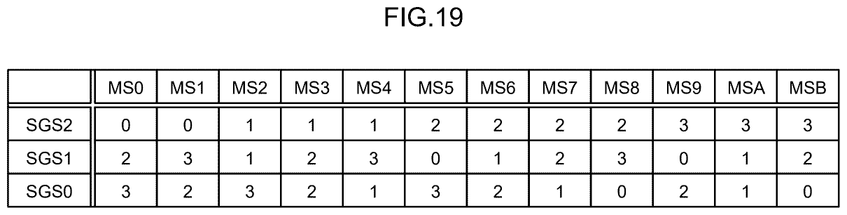

12 combinations in which the patterns of the levels are different from each other and the sum of the levels becomes 5 may be used and the levels of the 36 select transistors STS may be set as illustrated in FIG. 19. FIG. 19 is a diagram illustrating a state set in the select transistor STS. In FIG. 19, a level set to the select transistor STS is illustrated in decimal notation.

In the examples of FIGS. 18 and 19, the threshold voltages of the three layers of the select transistors STS0, STS1, and STS2 at the locations at which the three layers of the select gate lines SGS0, SGS1, and SGS2 and the memory string MS0 intersect are set to “3” level, “2” level, and “O” level, respectively.

The threshold voltages of the three layers of the select transistors STS0, STS1, and STS2 at the locations at which the three layers of the select gate lines SGS0, SGS1, and SGS2 and the memory string MS1 intersect are set to “2” level, “3” level, and “0” level, respectively.

The threshold voltages of the three layers of the select transistors STS0, STS1, and STS2 at the locations at which the three layers of the select gate lines SGS0, SGS1, and SGS2 and the memory string MS2 intersect are set to “3” level, “1” level, and “1” level, respectively.

The threshold voltages of the three layers of the select transistors STS0, STS1, and STS2 at the locations at which the three layers of the select gate lines SGS0, SGS1, and SGS2 and the memory string MS3 intersect are set to “2” level, “2” level, and “1” level, respectively.

The threshold voltages of the three layers of the select transistors STS0, STS1, and STS2 at the locations at which the three layers of the select gate lines SGS0, SGS1, and SGS2 and the memory string MS4 intersect are set to “1” level, “3” level, and “1” level, respectively.

The threshold voltages of the three layers of the select transistors STS0, STS1, and STS2 at the locations at which the three layers of the select gate lines SGS0, SGS1, and SGS2 and the memory string MS5 intersect are set to “3” level, “0” level, and “2” level, respectively.

The threshold voltages of the three layers of the select transistors STS0, STS1, and STS2 at the locations at which the three layers of the select gate lines SGS0, SGS1, and SGS2 and the memory string MS6 intersect are set to “2” level, “1” level, and “2” level, respectively.

The threshold voltages of the three layers of the select transistors STS0, STS1, and STS2 at the locations at which the three layers of the select gate lines SGS0, SGS1, and SGS2 and the memory string MS7 intersect are set to “1” level, “2” level, and “2” level, respectively.

The threshold voltages of the three layers of the select transistors STS0, STS1, and STS2 at the locations at which the three layers of the select gate lines SGS0, SGS1, and SGS2 and the memory string MS8 intersect are set to “0” level, “3” level, and “2” level, respectively.

The threshold voltages of the three layers of the select transistors STS0, STS1, and STS2 at the locations at which the three layers of the select gate lines SGS0, SGS1, and SGS2 and the memory string MS9 intersect are set to “2” level, “0” level, and “3” level, respectively.

The threshold voltages of the three layers of the select transistors STS0, STS1, and STS2 at the locations at which the three layers of the select gate lines SGS0, SGS1, and SGS2 and the memory string MSA intersect are set to “1” level, “1” level, and “3” level, respectively.

The threshold voltages of the three layers of the select transistors STS0, STS1, and STS2 at the locations at which the three layers of the select gate lines SGS0, SGS1, and SGS2 and the memory string MSB intersect are set to “0” level, “2” level, and “3” level, respectively.

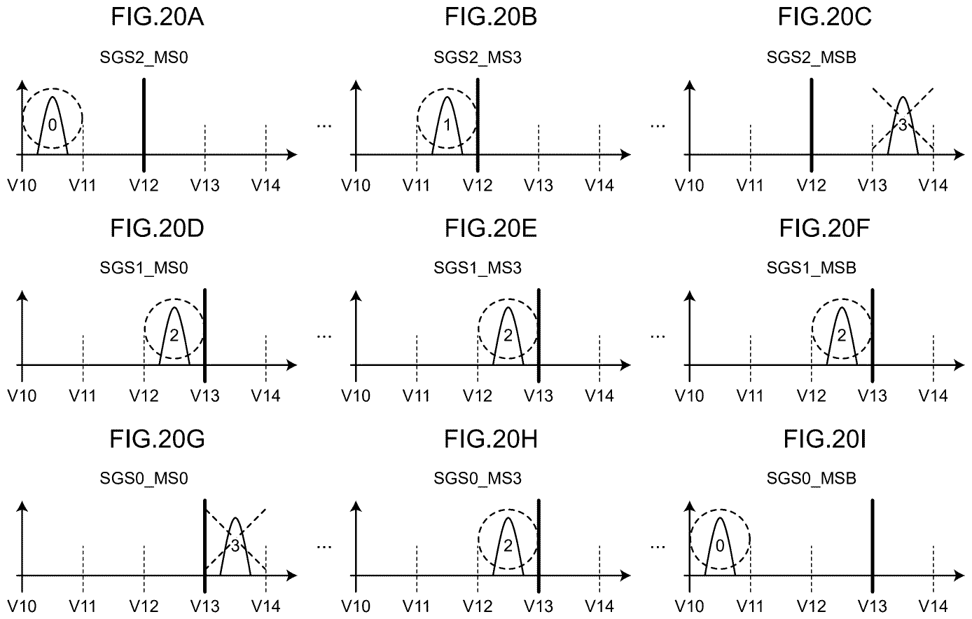

For example, as illustrated in FIGS. 18 and 20A to 201, electrical division that selectively conducts the memory string MS3 among the 12 memory strings MS0 to MSB and cuts off the other memory strings MS0 to MS2 and MS4 to MSB can be implemented by applying control voltages V13, V13, and V12 to each of the three layers of the select gate lines SGS0, SGS1, and SGS2. FIGS. 20A to 201 are diagrams illustrating a threshold value and an applied voltage of the select transistor STS.

When the control voltages V13, V13, and V12 are applied to each of the three layers of the select gate lines SGS0, SGS1, and SGS2, the three select transistors STS0, STS1, and STS2 of the memory string MS0 illustrated in FIGS. 18, 19, 20G, 20D, and 20A enter an off state, an on state, and an on state, respectively, and are cut off on the source side.

The three select transistors STS0, STS1, and STS2 of the memory string MS1 illustrated in FIGS. 18 and 19 enter an on state, an off state, and an off state, respectively, and are cut off on the source side.

The three select transistors STS0, STS1, and STS2 of the memory string MS2 illustrated in FIGS. 18 and 19 enter an off state, an on state, and an on state, respectively, and are cut off on the source side.

The three select transistors STS0, STS1, and STS2 of the memory string MS3 illustrated in FIGS. 18, 19, 20H, 20E, and 20B enter an on state, an on state, and an on state, respectively, and are selectively conducted on the source side.

The three select transistors STS0, STS1, and STS2 of the memory string MS4 illustrated in FIGS. 18 and 19 enter an on state, an off state, and an on state, respectively, and are cut off on the source side.

The three select transistors STS0, STS1, and STS2 of the memory string MS5 illustrated in FIGS. 18 and 19 enter an off state, an on state, and an off state, respectively, and are cut off on the source side.

The three select transistors STS0, STS1, and STS2 of the memory string MS6 illustrated in FIGS. 18 and 19 enter an on state, an on state, and an off state, respectively, and are cut off on the source side.

The three select transistors STS0, STS1, and STS2 of the memory string MS7 illustrated in FIGS. 18 and 19 enter an on state, an on state, and an off state, respectively, and are cut off on the source side.

The three select transistors STS0, STS1, and STS2 of the memory string MS8 illustrated in FIGS. 18 and 19 enter an on state, an off state, and an off state, respectively, and are cut off on the source side.

The three select transistors STS0, STS1, and STS2 of the memory string MS9 illustrated in FIGS. 18 and 19 enter an on state, an on state, and an off state, respectively, and are cut off on the source side.

The three select transistors STS0, STS1, and STS2 of the memory string MSA illustrated in FIGS. 18 and 19 enter an on state, an on state, and an off state, respectively, and are cut off on the source side.

The three select transistors STS0, STS1, and STS2 of the memory string MSB illustrated in FIGS. 18, 19, 201, 20F, and 20C enter an on state, an on state, and an off state, respectively, and are cut off on the source side.

As a result, on the source side, electrical division in which the memory string MS3 among the 12 memory strings MS0 to MSB is selectively conducted and the other memory strings MS0 to MS2 and MS4 to MSB are cut off can be implemented.

On the drain side, the select gate line SGD is physically divided into 12 select gate electrodes SGD0 to SGSB by the insulating film SHE illustrated in FIG. 18. 12 select transistors STD are formed at locations at which the 12 select gate electrodes SGD0 to SGSB and the 12 memory strings MS0 to MSB intersect. A select potential is applied to the select gate electrode SGD3, and a non-select potential is applied to the other select gate electrodes SGD0 to SGS2 and SGD4 to SGSB. As a result, the select transistor STD at a location at which the select gate electrode SGD3 and the memory string MS3 intersect is selectively turned on, and the other 11 select transistors STD are turned off. As a result, the memory string MS3 is selectively conducted on the drain side and the other memory strings MS0 to MS2 and MS4 to MSB are cut off.

In this way, in the semiconductor memory device 200i, even when the sum S of levels of states ST in each combination is larger than a level obtained by Equation 2, it is possible to secure a large divisor of electrical division of the memory strings MS while reducing the number of layers of the select gate lines SGS.

Alternatively, in each block BLK, instead of a configuration in which physical division is used on the drain side and electrical division is used on the source side, a configuration in which electrical division is used on the drain side and physical division is used on the source side may be applied, or a configuration in which electrical division is used on both the drain side and the source side may be applied.

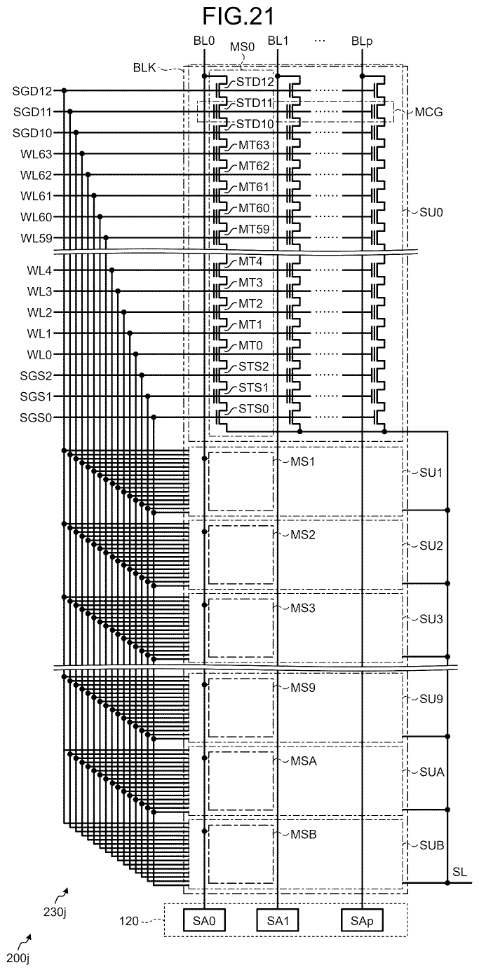

For example, as a second modification of the second embodiment, when the three layers of select gate lines SGD10 to SGD12 are stacked in the Z direction on the drain side and the three layers of the select gate lines SGS0 to SGS2 are stacked in the Z direction on the source side, a memory cell array 230j of a semiconductor memory device 200j may be configured as illustrated in FIG. 21. FIG. 21 is a circuit diagram illustrating a configuration of a block BLK in the second modification of the second embodiment.

In the block BLK illustrated in FIG. 21, three select gate lines SGD10 to SGD12 are disposed instead of 12 select gate electrodes SGD0 to SGDB (refer to FIG. 13). The 12 string units SU0 to SUB share each of the three select gate lines SGD10 to SGD12. Each memory string MS includes select transistors STD10 to STD12 instead of the select transistor STD (refer to FIG. 13). Each of the select transistors STD10 to STD12 include a control gate and a charge storage film, and stores a level in a nonvolatile manner.

The select transistors STD10 to STD12 on the drain side may be capable of storing a plurality of bit levels. For example, when each of the select transistors STD10 to STD12 is capable of storing a level of s (s≥2) bits, a size of a storage capacity per word line WL is equal to s physical pages. That is, each of the select transistors STD10 to STD12 is handled as s physical pages. Here, each of the select transistors STD10 to STD12 is capable of multi-level storage up to a 2^{s} level. That is, threshold voltages of the select transistors STD10 to STD12 can be set between 2^{s} or less levels.

For example, when s=2 is satisfied, each of the select transistors STD10 to STD12 may be capable of three-level storage. Here, as illustrated in FIG. 14, a range in which the threshold voltage is controlled (range of V0 to V3) is divided into four states (small regions) ST10 to ST13. The four states ST10 to ST13 correspond to 2-bit levels of “00”, “01”, “10”, and “11” from the lower-voltage side. When a level is represented by decimal notation, four states ST10 to ST13 correspond to four levels of “0”, “1”, “2”, and “3” from the lower-voltage side.

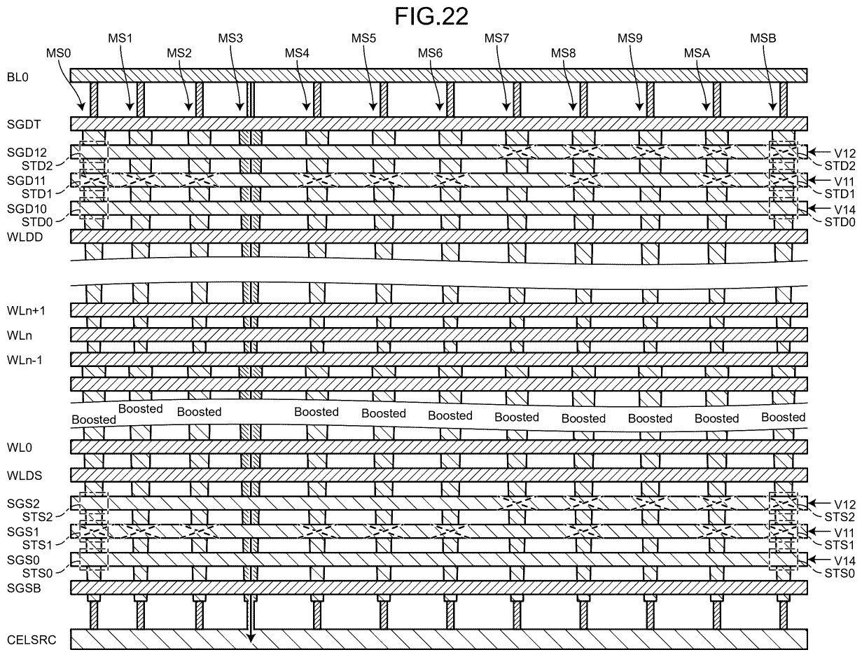

For example, 3×7=21 select transistors STD are formed at the locations at which the three layers of the select gate lines SGD10 to SGD12 and the 12 memory strings MS0 to MS6 illustrated in FIG. 22 intersect. FIG. 22 is a cross-sectional view illustrating a configuration and an operation of a block BLK in the second modification of the second embodiment.

In the configuration of FIG. 22, S=4 is obtained by substituting N=3 and M=4 into Equation 2 for the drain side. S=4 is obtained by substituting N=3 and M=4 into Equation 2 for the source side.

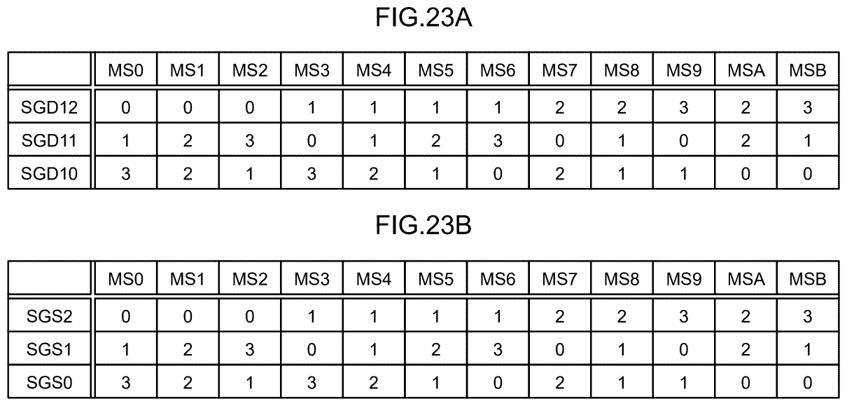

12 combinations in which patterns of levels are different from each other and a sum of the levels becomes 4 may be used and the levels of the 21 select transistors STD may be set as illustrated in FIG. 23A or the levels of the 21 select transistors STS may be set as illustrated in FIG. 23B. FIGS. 23A and 23B are diagrams illustrating states set to the select transistors STD and STS. In FIGS. 23A and 23B, the levels set to the select transistors STD and STS are illustrated in decimal notation.

Here, a combination of states of three select transistors STD1, STD2, and STD3 and a combination of states of three select transistors STS0, STS1, and STS2 may have the same level pattern for each of the memory strings MS0 to MSB.

In the example of FIGS. 22, 23A, and 23B, the threshold voltages of the three layers of the select transistors STD10, STD11, and STD12 at the locations at which the three layers of the select gate lines SGD10, SGD11, and SGD12 and the memory string MS0 intersect are set to “3” level, “1” level, and “0” level, respectively.

The threshold voltages of the three layers of the select transistors STD10, STD11, and STD12 at the locations at which the three layers of the select gate lines SGD10, SGD11, and SGD12 and the memory string MS1 intersect are set to “2” level, “2” level, and “0” level, respectively.

The threshold voltages of the three layers of the select transistors STD10, STD11, and STD12 at the locations at which the three layers of the select gate lines SGD10, SGD11, and SGD12 and the memory string MS2 intersect are set to “1” level, “3” level, and “O” level, respectively.

The threshold voltages of the three layers of the select transistors STD10, STD11, and STD12 at the locations at which the three layers of the select gate lines SGD10, SGD11, and SGD12 and the memory string MS3 intersect are set to “3” level, “0” level, and “1” level, respectively.

The threshold voltages of the three layers of the select transistors STD10, STD11, and STD12 at the locations at which the three layers of the select gate lines SGD10, SGD11, and SGD12 and the memory string MS4 intersect are set to “2” level, “1” level, and “1” level, respectively.

The threshold voltages of the three layers of the select transistors STD10, STD11, and STD12 at the locations at which the three layers of the select gate lines SGD10, SGD11, and SGD12 and the memory string MS5 intersect are set to “1” level, “2” level, and “1” level, respectively.

The threshold voltages of the three layers of the select transistors STD10, STD11, and STD12 at the locations at which the three layers of the select gate lines SGD10, SGD11, and SGD12 and the memory string MS6 intersect are set to “0” level, “3” level, and “1” level, respectively.

The threshold voltages of the three layers of the select transistors STD10, STD11, and STD12 at the locations at which the three layers of the select gate lines SGD10, SGD11, and SGD12 and the memory string MS7 intersect are set to “2” level, “O” level, and “2” level, respectively.

The threshold voltages of the three layers of the select transistors STD10, STD11, and STD12 at the locations at which the three layers of the select gate lines SGD10, SGD11, and SGD12 and the memory string MS8 intersect are set to “1” level, “1” level, and “2” level, respectively.

The threshold voltages of the three layers of the select transistors STD10, STD11, and STD12 at the locations at which the three layers of the select gate lines SGD10, SGD11, and SGD12 and the memory string MS9 intersect are set to “1” level, “0” level, and “3” level, respectively.

The threshold voltages of the three layers of the select transistors STD10, STD11, and STD12 at the locations at which the three layers of the select gate lines SGD10, SGD11, and SGD12 and the memory string MSA intersect are set to “0” level, “2” level, and “2” level, respectively.

The threshold voltages of the three layers of the select transistors STD10, STD11, and STD12 at the locations at which the three layers of the select gate lines SGD10, SGD11, and SGD12 and the memory string MSB intersect are set to “0” level, “1” level, and “3” level, respectively.

For example, as illustrated in FIG. 22, electrical division that selectively conducts the memory string MS3 among the 12 memory strings MS0 to MSB and cuts off the other memory strings MS0 to MS2 and MS4 to MSB can be implemented by applying the control voltages V14, V11, and V12 to each of the three layers of the select gate lines SGD10, SGD11, and SGD12.

When the control voltages V14, V11, and V12 are applied to each of the three layers of the select gate lines SGD10, SGD11, and SGD12, the three select transistors STD10, STD11, and STD12 of the memory string MS0 enter an on state, an off state, and an on state, respectively, and are cut off on the drain side.

The three select transistors STD10, STD11, and STD12 of the memory string MS1 enter an on state, an off state, and an on state, respectively, and are cut off on the drain side.

The three select transistors STD10, STD11, and STD12 of the memory string MS2 enter an on state, an off state, and an on state, respectively, and are cut off on the drain side.

The three select transistors STD10, STD11, and STD12 of the memory string MS3 enter an on state, an on state, and an on state, respectively, and are selectively conducted on the drain side.

The three select transistors STD10, STD11, and STD12 of the memory string MS4 enter an on state, an off state, and an on state, respectively, and are cut off on the drain side.

The three select transistors STD10, STD11, and STD12 of the memory string MS5 enter an on state, an off state, and an on state, respectively, and are cut off on the drain side.

The three select transistors STD10, STD11, and STD12 of the memory string MS6 enter an on state, an off state, and an on state, respectively, and are cut off on the drain side.

The three select transistors STD10, STD11, and STD12 of the memory string MS7 enter an on state, an on state, and an off state, respectively, and are cut off on the drain side.

The three select transistors STD10, STD11, and STD12 of the memory string MS8 enter an on state, an off state, and an off state, respectively, and are cut off on the drain side.

The three select transistors STD10, STD11, and STD12 of the memory string MS9 enter an on state, an on state, and an off state, respectively, and are cut off on the drain side.

The three select transistors STD10, STD11, and STD12 of the memory string MSA enter an on state, an off state, and an off state, respectively, and are cut off on the drain side.

The three select transistors STD10, STD11, and STD12 of the memory string MSB enter an on state, an off state, and an off state, respectively, and are cut off on the drain side.

As a result, electrical division in which the memory string MS3 among the 12 memory strings MS0 to MSB is selectively conducted and the other memory strings MS0 to MS2 and MS4 to MSB are cut off can be implemented on the drain side.

Here, on the source side, electrical division in which the memory string MS3 among the 12 memory strings MS0 to MSB is selectively conducted and the other memory strings MS0 to MS2 and MS4 to MSB are cut off can be implemented as in the embodiment.

In this way, in the memory cell array 230j of the semiconductor memory device 200j, each of the select transistors STD and STS perform multi-level storage on the drain side and the source side. Accordingly, it is possible to secure a large divisor of the memory strings MS while reducing the number of layers of the select gate lines SGD and SGS on each of the drain side and the source side and efficiently perform electrical division of the memory strings MS.

### Third Embodiment

Next, a semiconductor memory device 300 according to a third embodiment will be described. Hereinafter, portions different from those of the first embodiment and the second embodiment will be mainly described.

In the first embodiment, a configuration in which each select transistor STS perform three-level storage is exemplified and in the second embodiment, a configuration in which each select transistor STS perform four-level storage is exemplified, but in the third embodiment, a configuration in which each select transistor STS performs five-level storage is exemplified.

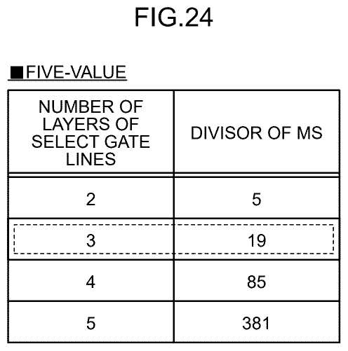

For example, when the plurality of select transistors STS are capable of five-level storage, as illustrated in FIG. 24, it is possible to stack two layers of the select gate lines SGS in the Z direction and electrically divide the memory strings MS into five at most. When the three layers of the select gate lines SGS are stacked in the Z direction, it is possible to take a combination in which permutations of states of the select transistors STS are different from each other in each memory string and sums of the permutations are equal to each other and electrically divide the memory strings MS into 19 at most. It is possible to stack four layers of the select gate lines SGS in the Z direction and electrically divide the memory strings MS into 85 at most. It is possible to stack five layers of the select gate lines SGS in the Z direction and electrically divide the memory strings MS into 381 at most.

As illustrated in FIG. 24, when the plurality of select transistors STS are capable of five-level storage, the number of layers of the select gate lines SGS per divisor of electrical division of the memory strings MS can be reduced by electrical division.

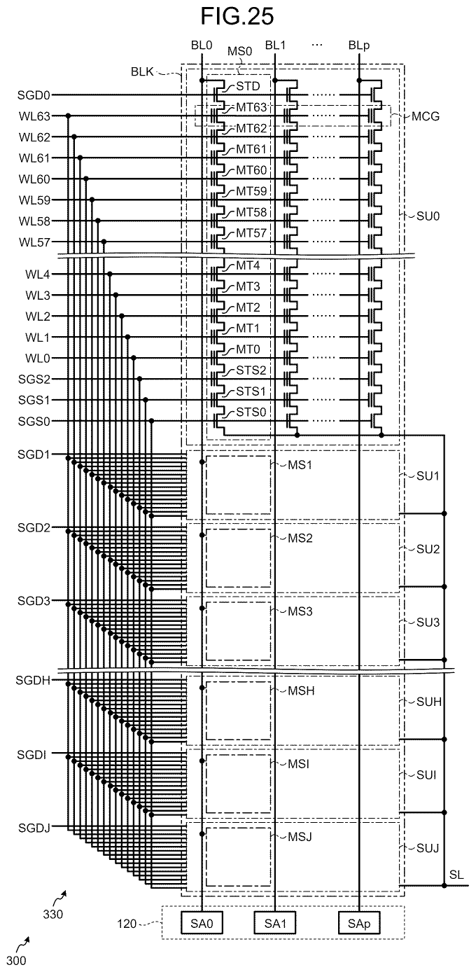

When the three layers of the select gate lines SGS0 to SGS2 are stacked in the Z direction, a memory cell array 330 of the semiconductor memory device 300 may be configured as illustrated in FIG. 25 since the memory strings MS can be electrically divided into 19 at most. FIG. 25 is a circuit diagram illustrating a configuration of a block BLK in the third embodiment.

The memory cell array 330 includes a plurality of blocks BLK. Each block BLK includes 19 string units SU0 to SUJ as illustrated in FIG. 25 since the memory strings MS can be electrically divided into 19 at most. The 19 string units SU0 to SUJ correspond to 19 select gate electrodes SGD0 to SGDJ. The 19 string units SU0 to SUJ share each of the three select gate lines SGS0 to SGS2. Each of the string units SU0 to SUJ is selectively accessible by the select gate electrodes SGD0 to SGDJ. The string unit SU0 includes a plurality of memory strings MS0. The string unit SU1 includes a plurality of memory strings MS1. The string unit SU2 includes a plurality of memory strings MS2. The string unit SUJ includes a plurality of memory strings MSJ. 19 memory strings MS across the 19 string units SU are commonly connected to one bit line BL.

Each of the select transistors STS0 to STS2 on the source side may be capable of storing a plurality of bit levels. For example, when each of the select transistors STS0 to STS2 is capable of storing a level of s (s≥2) bits, a size of a storage capacity per word line WL is equal to s physical pages. That is, each of the select transistors STS0 to STS2 is handled as s physical pages. Here, each of the select transistors STS0 to STS2 is capable of multi-level storage up to a 2^{s} level. That is, a threshold voltage of each of the select transistors STS0 to STS2 can be set between 2^{s} or less levels.

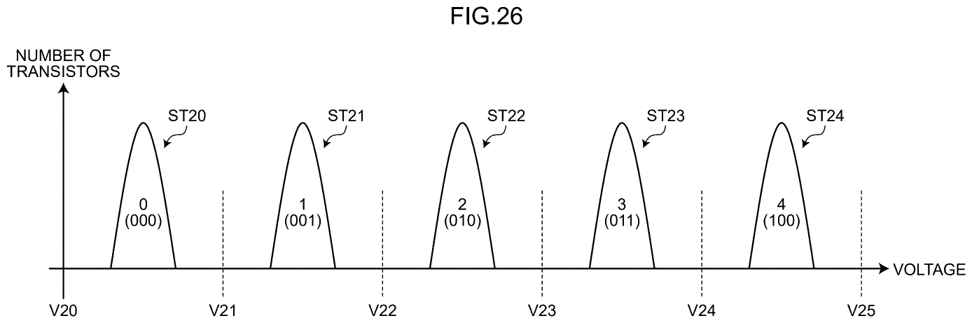

For example, when s=3 is satisfied, each of the select transistors STS0 to STS2 may be capable of five-level storage. Here, as illustrated in FIG. 26, a range in which the threshold voltage is controlled (range of V20 to V25) is divided into five states (small regions) ST20 to ST24. FIG. 26 is a diagram illustrating a threshold distribution of the select transistor STS in the third embodiment. A different 3-bit levels is associated with each of the states ST20 to ST24. In the example of FIG. 26, a boundary between the state ST20 and the state ST21 is defined as V21, a boundary between the state ST21 and the state ST22 is defined as V22, a boundary between the state ST22 and the state ST23 is defined as V23, and a boundary between the state ST23 and the state ST24 is defined as V24. Here, the following Equation 4 is satisfied.

$$V 20 < V 21 < V 22 < V 23 < V 24 < V 25 \qquad Equation 4$$

In the example of FIG. 26, the five states ST20 to ST25 correspond to 3-bit levels of “000”, “001”, “010”, “011”, and “100” from the lower-voltage side. When a level is represented by decimal notation, the five states ST20 to ST25 correspond to five levels of “0”, “1”, “2”, “3”, and “4” from the lower-voltage side. That is, a 3-bit level is associated with each state in ascending order from the lower-voltage side.

Although not illustrated, for example, 3×19=57 select transistors STS are formed at locations at which the three layers of the select gate lines SGS0 to SGS2 and the 19 memory strings MS0 to MSB intersect.

Levels set to the 57 select transistors STS include 19 combinations of states of the select transistors STS0, STS1, and STS2 for each of the memory strings MS0 to MSJ. By making patterns of states in each combination different from each other and making sums of the states in each combination equal to each other, it is possible to maximize the number of electrically divided memory strings. The sum S of levels of states ST in each combination may be obtained using Equation 2.

In such a configuration, S=6 is obtained by substituting N=3 and M=5 into Equation 2 for the source side.

19 combinations in which patterns of levels are different from each other and a sum of the levels becomes 6 may be used and the levels of 57 select transistors STS may be set.

For example, the threshold voltages of the three layers of the select transistors STS0, STS1, and STS2 at the locations at which the three layers of the select gate lines SGS0, SGS1, and SGS2 and the memory string MS0 intersect are set to “4” level, “2” level, and “0” level, respectively.

The threshold voltages of the three layers of the select transistors STS0, STS1, and STS2 at the locations at which the three layers of the select gate lines SGS0, SGS1, and SGS2 and the memory string MS1 intersect are set to “3” level, “3” level, and “0” level, respectively.

The threshold voltages of the three layers of the select transistors STS0, STS1, and STS2 at the locations at which the three layers of the select gate lines SGS0, SGS1, and SGS2 and the memory string MS2 intersect are set to “2” level, “4” level, and “0” level, respectively.

The threshold voltages of the three layers of the select transistors STS0, STS1, and STS2 at the locations at which the three layers of the select gate lines SGS0, SGS1, and SGS2 and the memory string MS3 intersect are set to “4” level, “0” level, and “2” level, respectively.

The threshold voltages of the three layers of the select transistors STS0, STS1, and STS2 at the locations at which the three layers of the select gate lines SGS0, SGS1, and SGS2 and the memory string MS4 intersect are set to “3” level, “2” level, and “1” level, respectively.

### (Skip)

The threshold voltages of the three layers of the select transistors STS0, STS1, and STS2 at the locations at which the three layers of the select gate lines SGS0, SGS1, and SGS2 and the memory string MSJ intersect are set to “0” level, “2” level, and “4” level, respectively.

For example, electrical division that selectively conducts the memory string MS3 among the 19 memory strings MS0 to MSJ and cuts off the other memory strings MS0 to MS2 and MS4 to MSJ can be implemented by applying control voltages V25, V21, and V23 to each of the three layers of the select gate lines SGS0, SGS1, and SGS2.

When the control voltages V25, V21, and V23 are applied to each of the three layers of the select gate lines SGS0, SGS1, and SGS2, the three select transistors STS0, STS1, and STS2 of the memory string MS0 enter an off state, an off state, and an on state, respectively, and are cut off on the source side.

The three select transistors STS0, STS1, and STS2 of the memory string MS1 enter an on state, an off state, and an on state, respectively, and are cut off on the source side.

The three select transistors STS0, STS1, and STS2 of the memory string MS2 enter an on state, an off state, and an on state, respectively, and are cut off on the source side.

The three select transistors STS0, STS1, and STS2 of the memory string MS3 enter an on state, an on state, and an on state, respectively, and are selectively conducted on the source side.

The three select transistors STS0, STS1, and STS2 of the memory string MS4 enter an on state, an off state, and an on state, respectively, and are cut off on the source side.

### (Skip)

The three select transistors STS0, STS1, and STS2 of the memory string MSJ enter an on state, an off state, and an on state, respectively, and are cut off on the source side.

As a result, on the source side, electrical division in which the memory string MS3 among the 19 memory strings MS0 to MSJ is selectively conducted and the other memory strings MS0 to MS2 and MS4 to MSJ are cut off can be implemented.

On the drain side, the select gate line SGD is physically divided into 19 select gate electrodes SGD0 to SGSJ by the insulating film SHE. 19 select transistors STD are formed at locations at which the 19 select gate electrodes SGD0 to SGSJ and the 19 memory strings MS0 to MSJ intersect. A select potential is applied to the select gate electrode SGD3, and a non-select potential is applied to the other select gate electrodes SGD0 to SGS2 and SGD4 to SGSJ. As a result, the select transistor STD at a location at which the select gate electrode SGD3 and the memory string MS3 intersect is selectively turned on, and the other 11 select transistors STD are turned off. As a result, the memory string MS3 is selectively conducted on the drain side and the other memory strings MS0 to MS2 and MS4 to MSJ are cut off.

As described above, in the third embodiment, each select transistor STS is capable of five-level storage in the semiconductor memory device 100. As a result, it is possible to secure a large divisor of electrical division of the memory strings MS while reducing the number of layers of the select gate lines SGS and efficiently perform electrical division of the memory strings MS.

Note that, when each select transistor STS is capable of five-level storage and the three layers of the select gate lines SGS are stacked in the Z direction, in the memory cell array 130, each block BLK may include 18 or less string units SU since the memory strings MS can be electrically divided into 19 at most.

Alternatively, although not illustrated, when each select transistor STS is capable of five-level storage and two layers of the select gate lines SGS are stacked in the Z direction, in the memory cell array 130, each block BLK may include K string units SU since the memory strings MS can be electrically divided into five at most. K is an integer of 1 or more and 5 or less. Here, the K string units SU correspond to K select gate electrodes SGD. The K string units SU share each of the two select gate lines SGS. Each of the string units SU is selectively accessible by the select gate electrodes SGD. Each string unit SU includes a plurality of memory strings MS. K memory strings MS across the K string units SU are commonly connected to one bit line BL.

In this way, since each select transistor STS performs five-level storage, the K memory strings MS commonly connected to one bit line BL can be electrically divided.

Alternatively, when each select transistor STS is capable of five-level storage and four layers of the select gate lines SGS are stacked in the Z direction, in the memory cell array 130, each block BLK may include K string units SU since the memory strings MS can be electrically divided into 85 at most. K is an integer of 1 or more and 85 or less. Here, the K string units SU correspond to K select gate electrodes SGD. The K string units SU share each of the four select gate lines SGS. Each of the string units SU is selectively accessible by the select gate electrodes SGD. Each string unit SU includes a plurality of memory strings MS. K memory strings MS across the K string units SU are commonly connected to one bit line BL.

In this way, since each select transistor STS performs five-level storage, the K memory strings MS commonly connected to one bit line BL can be electrically divided.

Alternatively, when each select transistor STS is capable of five-level storage and five layers of the select gate lines SGS are stacked in the Z direction, in the memory cell array 130, each block BLK may include K string units SU since the memory strings MS can be electrically divided into 381 at most. K is an integer of 1 or more and 381 or less. Here, the K string units SU correspond to K select gate electrodes SGD. The K string units SU share each of the five select gate lines SGS. Each of the string units SU is selectively accessible by the select gate electrodes SGD. Each string unit SU includes a plurality of memory strings MS. K memory strings MS across the K string units SU are commonly connected to one bit line BL.

In this way, since each select transistor STS performs five-level storage, the K memory strings MS commonly connected to one bit line BL can be electrically divided.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a first memory string that includes a first select transistor, a second select transistor connected to the first select transistor, and a plurality of first memory cell transistors connected to the second select transistor;
a second memory string that includes a third select transistor, a fourth select transistor connected to the third select transistor, and a plurality of second memory cell transistors connected to the fourth select transistor;
a first select gate line connected to a gate of the first select transistor and a gate of the third select transistor;
a second select gate line connected to a gate of the second select transistor and a gate of the fourth select transistor; and
a plurality of word lines corresponding to the plurality of first memory cell transistors and corresponding to the plurality of second memory cell transistors, each of the plurality of word lines being connected to a gate of a corresponding first memory cell transistor and a gate of a corresponding second memory cell transistor, wherein
each of states of the first select transistor, the second select transistor, the third select transistor, and the fourth select transistor is capable of being set between three levels.

2. The semiconductor memory device according to claim 1, wherein
a first combination of the state of the first select transistor and the state of the second select transistor and a second combination of the state of the third select transistor and the state of the fourth select transistor are different from each other.

3. The semiconductor memory device according to claim 2, wherein
a sum of the states in the first combination is equal to a sum of the states in the second combination.

4. The semiconductor memory device according to claim 1, wherein
each of the first select transistor, the second select transistor, the third select transistor, and the fourth select transistor stores a level in a nonvolatile manner.

5. The semiconductor memory device according to claim 1, wherein
in the first memory string, the first select transistor and the second select transistor are connected between the plurality of first memory cell transistors and a source line, and
in the second memory string, the third select transistor and the fourth select transistor are connected between the plurality of second memory cell transistors and the source line.

6. The semiconductor memory device according to claim 1, wherein
the first memory string further includes a fifth select transistor connected to the plurality of first memory cell transistors on an opposite side of the second select transistor, and a sixth select transistor connected to the fifth select transistor,
the second memory string further includes a seventh select transistor connected to the plurality of second memory cell transistors on an opposite side of the third select transistor, and
an eighth select transistor connected to the seventh select transistor, and
each of states of the fifth select transistor, the sixth select transistor, the seventh select transistor, and the eighth select transistor is capable of being set between three levels.

7. The semiconductor memory device according to claim 6, wherein
in the first memory string, the first select transistor and the second select transistor are connected between the plurality of first memory cell transistors and a source line, and the fifth select transistor and the sixth select transistor are connected between the plurality of first memory cell transistors and a bit line, and
in the second memory string, the third select transistor and the fourth select transistor are connected between the plurality of second memory cell transistors and the source line, and the seventh select transistor and the eighth select transistor are connected between the plurality of second memory cell transistors and the bit line.

8. A semiconductor memory device comprising:
a first memory string that includes a first select transistor, a second select transistor connected to the first select transistor, and a plurality of first memory cell transistors connected to the second select transistor;
a second memory string that includes a third select transistor, a fourth select transistor connected to the third select transistor, and a plurality of second memory cell transistors connected to the fourth select transistor;
a first select gate line connected to a gate of the first select transistor and a gate of the third select transistor;
a second select gate line connected to a gate of the second select transistor and a gate of the fourth select transistor; and
a plurality of word lines corresponding to the plurality of first memory cell transistors and corresponding to the plurality of second memory cell transistors, each of the plurality of word lines being connected to a gate of a corresponding first memory cell transistor and a gate of a corresponding second memory cell transistor, wherein
each of states of the first select transistor, the second select transistor, the third select transistor, and the fourth select transistor is capable of being set between five or more levels.

9. The semiconductor memory device according to claim 8, wherein
a first combination of the state of the first select transistor and the state of the second select transistor and a second combination of the state of the third select transistor and the state of the fourth select transistor are different from each other.

10. The semiconductor memory device according to claim 9, wherein
a sum of the states in the first combination is equal to a sum of the states in the second combination.

11. The semiconductor memory device according to claim 1, wherein
each of the first select transistor, the second select transistor, the third select transistor, and the fourth select transistor stores a level in a nonvolatile manner.

12. The semiconductor memory device according to claim 8, wherein
in the first memory string, the first select transistor and the second select transistor are connected between the plurality of first memory cell transistors and a source line, and
in the second memory string, the third select transistor and the fourth select transistor are connected between the plurality of second memory cell transistors and the source line.

13. The semiconductor memory device according to claim 8, wherein
the first memory string further includes a fifth select transistor connected to the plurality of first memory cell transistors on an opposite side of the second select transistor, and a sixth select transistor connected to the fifth select transistor,
the second memory string further includes a seventh select transistor connected to the plurality of second memory cell transistors on an opposite side of the third select transistor, and
an eighth select transistor connected to the seventh select transistor, and
each of states of the fifth select transistor, the sixth select transistor, the seventh select transistor, and the eighth select transistor is capable of being set between five or more levels.

14. The semiconductor memory device according to claim 11, wherein
in the first memory string, the first select transistor and the second select transistor are connected between the plurality of first memory cell transistors and a source line, and the fifth select transistor and the sixth select transistor are connected between the plurality of first memory cell transistors and a first bit line, and
in the second memory string, the third select transistor and the fourth select transistor are connected between the plurality of second memory cell transistors and the source line, and the seventh select transistor and the eighth select transistor are connected between the plurality of second memory cell transistors and a second bit line.

15. A semiconductor memory device comprising:
a first memory string that includes a first select transistor, a second select transistor connected to the first select transistor, a third select transistor connected to the second select transistor, and a plurality of first memory cell transistors connected to the third select transistor;
a second memory string that includes a fourth select transistor, a fifth select transistor connected to the fourth select transistor, a sixth select transistor connected to the fifth select transistor, and a plurality of second memory cell transistors connected to the sixth select transistor;
a first select gate line connected to a gate of the first select transistor and a gate of the fourth select transistor;
a second select gate line connected to a gate of the second select transistor and a gate of the fifth select transistor;
a word line connected to a gate of the third select transistor and a gate of the sixth select transistor; and
a plurality of fourth word lines corresponding to the plurality of first memory cell transistors and corresponding to the plurality of second memory cell transistors, each of the plurality of fourth word lines being connected to a gate of a corresponding first memory cell transistor and a gate of a corresponding second memory cell transistor, wherein
each of states of the first select transistor, the second select transistor, the third select transistor, the fourth select transistor, the fifth select transistor, and the sixth select transistor is capable of being set between three or more levels.

16. The semiconductor memory device according to claim 15, wherein
a third combination of the state of the first select transistor, the state of the second select transistor, and the state of the third select transistor and a fourth combination of the state of the fourth select transistor, a threshold voltage of the fifth select transistor, and the state of the sixth select transistor are different from each other.

17. The semiconductor memory device according to claim 16, wherein
a sum of the states in the third combination is equal to a sum of the states in the fourth combination.

18. The semiconductor memory device according to claim 15, wherein
in the first memory string, the first select transistor, the second select transistor, and the third select transistor are connected between the plurality of first memory cell transistors and a source line, and
in the second memory string, the fourth select transistor, the fifth select transistor, and the sixth select transistor are connected between the plurality of second memory cell transistors and the source line.

19. The semiconductor memory device according to claim 15, wherein
the first memory string further includes a seventh select transistor connected to the plurality of first memory cell transistors on an opposite side of the third select transistor, an eighth select transistor connected to the seventh select transistor, and a ninth select transistor connected to the eighth select transistor,
the second memory string further includes a tenth select transistor connected to the plurality of second memory cell transistors on an opposite side of the sixth select transistor, an eleventh select transistor connected to the tenth select transistor, and a twelfth select transistor connected to the eleventh select transistor, and
each of states of the seventh select transistor, the eighth select transistor, the ninth select transistor, the tenth select transistor, the eleventh select transistor, and the twelfth select transistor is capable of being set between three or more levels.

20. The semiconductor memory device according to claim 19, wherein
in the first memory string, the first select transistor, the second select transistor, and the third select transistor are connected between the plurality of first memory cell transistors and a source line, and the seventh select transistor, the eighth select transistor, and the ninth select transistor are connected between the plurality of first memory cell transistors and a first bit line, and
in the second memory string, the fourth select transistor, the fifth select transistor, and the sixth select transistor are connected between the plurality of second memory cell transistors and the source line, and the tenth select transistor, the eleventh select transistor, and the twelfth select transistor are connected between the plurality of second memory cell transistors and a second bit line.
